(19) United States
(12) Patent Application Publication
(10) Pub. No.: US 2009/0314327 A1
(43) Pub. Date: Dec. 24, 2009

(54) PHOTOVOLTAIC MODULE

(75) Inventors: Ivan Saha, Chennai (IN); Amitabh Verma, Chennai (IN); Vineet Sharma, Chennai (IN)

Correspondence Address: DARBY & DARBY P.C., P.O. BOX 770, Church Street Station, New York, NY, 10008-0770, US

(73) Assignee: MOSER BAER PHOTOVOLTAIC LIMITED, Chennai (IN)

(21) Appl. No.: 12/178,020

(22) Filed: Jul. 23, 2008

(30) Foreign Application Priority Data
Jun. 24, 2008 (IN) 2008/CHE/007140

(51) Int. Cl. H01L 31/042

(52) U.S. Cl. 136/246

(57) ABSTRACT

Embodiments include an apparatus for generating electricity from solar energy, said apparatus comprising a base substrate for; a plurality of connectors attached to said base substrate, wherein connecting spaces are formed between adjacent said connectors; one or more photovoltaic strips arranged in said connecting spaces over said base substrate; a plurality of optical vees for concentrating solar energy over said photovoltaic strips, said optical vees being connected to said base substrate through said connectors, said optical vees comprising a reflective layer or surface, such that rays incident on said reflective layer or surface are reflected towards said photovoltaic strips; and a transparent member positioned over said optical vees, wherein said base substrate, said connectors, said photovoltaic strips, said optical vees and said transparent member form said apparatus in an integrated manner. Other embodiments include systems for generating electricity using the photovoltaic module. Yet other embodiments relate to methods of manufacturing the photovoltaic module and systems for generating electricity using the photovoltaic module.

### CROSS REFERENCE TO RELATED APPLICATIONS

This application claims the benefit of Indian Patent Application Number 2008/CHE/007140, filed on Jun. 24, 2008, which is hereby incorporated by reference in its entirety.

### BACKGROUND

The present invention relates, in general, to photovoltaic modules. More specifically, the present invention relates to a system and apparatus for connecting concentrating units in a photovoltaic module.

A photovoltaic module generates electricity from solar energy by the photoelectric effect. Typically, a low concentrator photovoltaic module includes a plurality of concentrating units and photovoltaic cells mounted on a base. The concentrating units may, for example, be connected to the base through various techniques, such as adhesives, screws, welding, or soldering.

However, the existing techniques do not provide a firm connection between the concentrating units and the base. Therefore, connections so provided may loosen after certain period of time. Further, these techniques require high precision that in turn leads to increase in the cost of manufacturing the photovoltaic module. Moreover, these techniques are not suitable for mass manufacturing.

In light of the foregoing discussion, there is a need for a photovoltaic module (and a fabrication method and system thereof) that is suitable for mass manufacturing, provides a mode for connecting concentrating units to the base, is quick to manufacture, and has lower cost.

### SUMMARY

An object of the present invention is to provide a system and apparatus for connecting a plurality of concentrating units to a base substrate in a photovoltaic module.

Another object of the present invention is to provide a photovoltaic module that is suitable for mass manufacturing.

Yet another object of the present invention is to provide a photovoltaic module that is easy and quick to manufacture.

Still another object of the present invention is to provide a photovoltaic module that has lower cost.

Embodiments of the present invention provide a photovoltaic module for generating electricity from solar energy. The photovoltaic module includes a base substrate for providing support to the photovoltaic module. A plurality of connectors is attached to the base substrate, such that the connectors form a plurality of connecting spaces between adjacent connectors. The connectors may, for example, be angular elements, Z-shaped elements, or flexible elements. One or more photovoltaic strips are arranged in the connecting spaces over the base substrate. The photovoltaic strips are connected through one or more conductors in a predefined manner. The predefined manner may, for example, be a series and/or parallel arrangement, such that electrical output is maximized. In an embodiment of the present invention, the photovoltaic strips may be formed by dicing a semiconductor wafer.

A plurality of optical vees is connected to the base substrate through the connectors. The optical vees are capable of concentrating solar energy over the photovoltaic strips. The optical vees have a reflective layer or surface, such that sun rays incident on the reflective layer or surface are reflected towards the photovoltaic strips. When the reflected sun rays fall on the photovoltaic strips, electricity is generated by the photoelectric effect.

The optical vees may be either hollow of solid. These optical vees may, for example, be made of a glass, a plastic, a polymeric material, ethyl vinyl acetate (EVA), thermoplastic poly-urethane (TPU), poly vinyl butyral (PVB), a silicone, an acrylic, a polycarbonate, a metal, a metallic alloy, a metal compound, and a ceramic. In accordance with an embodiment of the present invention, the optical vees comprise a reflection-enhancing layer to enhance the reflectivity of the optical vees.

In an embodiment of the present invention, the optical vees are formed by machining and polishing solid blocks of a reflective material. In another embodiment of the present invention, the optical vees are formed by polishing a sheet of a reflective material, which may be bent in a desired shape of the optical vees. In yet another embodiment of the present invention, the optical vees are made of a foil of a reflective material sandwiched between two moldable sheets. The sandwiched foil is bent in a desired shape of the optical vees. In still another embodiment of the present invention, the optical vees are formed by molding a polymeric material, and coating the optical vees with a reflective material to form the reflective layer or surface.

A transparent member is positioned over the optical vees. In accordance with an embodiment of the present invention, the transparent member is sealed with the base substrate. In accordance with an embodiment of the present invention, the base substrate, the connectors, the photovoltaic strips, the optical vees and the transparent member form the photovoltaic module in an integrated manner. In accordance with an embodiment of the present invention, the transparent member is coated with an anti-reflective coating to reduce loss of solar energy incident on the photovoltaic module.

The connectors provide a firm connection between the optical vees and the base substrate. In an embodiment of the present invention, the optical vees are slided through the connectors. This makes the process of connecting the optical vees with the base substrate easy and quick, thereby making it suitable for mass manufacturing.

### BRIEF DESCRIPTION OF DRAWINGS

Embodiments of the present invention will hereinafter be described in conjunction with the appended drawings provided to illustrate and not to limit the present invention, wherein like designations denote like elements, and in which:

FIG. 1 illustrates a blown-up view of a photovoltaic module 100, in accordance with an embodiment of the present invention;

FIG. 2 illustrates an arrangement 200 of a plurality of optical vees over a base substrate through a plurality of connectors, in accordance with an embodiment of the present invention;

FIGS. 3a, 3b, 3c, and 3d illustrate various stages of formation of arrangement 200, in accordance with an embodiment the present invention;

FIGS. 4a and 4b illustrate an arrangement 400 of a plurality of optical vees over a base substrate through a plurality of connectors, in accordance with another embodiment of the present invention;

FIGS. 5a, 5b, 5c and 5d illustrate various stages of formation of arrangement 500, in accordance with another embodiment of the present invention;

FIG. 6 illustrates an arrangement 600 of a plurality of optical vees over a base substrate through a plurality of connectors, in accordance with another embodiment of the present invention;

FIGS. 7a, 7b, 7c and 7d illustrate various stages of formation of arrangement 600, in accordance with another embodiment the present invention;

FIGS. 8a and 8b illustrate various stages of arrangement, in accordance with an embodiment of the present invention;

FIG. 9 illustrates a cross-sectional view of photovoltaic module 100, in accordance with an embodiment of the present invention;

FIG. 10 illustrates how photovoltaic strips 104 are connected through a plurality of conductors, in accordance with an embodiment of the present invention;

FIG. 11 illustrates an arrangement 1100 of photovoltaic strip 104a between solid optical vees 106a and 306b, in accordance with an embodiment of the present invention;

FIG. 12 illustrates an optical vee 1200, in accordance with yet another embodiment of the present invention;

FIG. 13 illustrates an arrangement 1300 of photovoltaic strip 104a between solid optical vees 106a and 106b, in accordance with still another embodiment of the present invention;

FIG. 14 is a perspective view of a string configuration 1400 of photovoltaic strips, in accordance with an embodiment of the present invention;

FIG. 15 is a perspective view illustrating optical vees 106 placed with string configuration 1400, in accordance with an embodiment of the present invention;

FIG. 16 is a perspective view illustrating a lay-up of a transparent member 108 over optical vees 106, in accordance with an embodiment of the present invention;

FIG. 17 is a blown-up view of a photovoltaic module 1700, in accordance with an embodiment of the present invention;

FIG. 18 illustrates a system 1800 for manufacturing a photovoltaic module, in accordance with an embodiment of the present invention;

FIG. 19 is a flow diagram illustrating a method for fabricating a photovoltaic module, in accordance with an embodiment of the present invention;

FIG. 20 is a flow diagram illustrating a method for manufacturing a photovoltaic module, in accordance with another embodiment of the present invention;

FIG. 21a-d illustrate various methods of fabricating optical vees, in accordance with an embodiment of the present invention;

FIG. 22 illustrates a system 2200 for generating electricity from solar energy, in accordance with an embodiment of the present invention;

FIG. 23 illustrates a system 2300 for generating electricity from solar energy, in accordance with another embodiment of the present invention;

FIG. 24 illustrates a method for manufacturing a system for generating electricity from solar energy, in accordance with an embodiment of the present invention;

FIG. 25 illustrates a method for manufacturing a system for generating electricity from solar energy, in accordance with another embodiment of the present invention;

FIG. 26 illustrates how the level of concentration can be varied, in accordance with an embodiment of the present invention;

FIG. 27 illustrates how the level of concentration can be varied, in accordance with an embodiment of the present invention;

FIG. 28 is a cross-sectional view illustrating how electromagnetic radiation is concentrated over photovoltaic strips 104, in accordance with an embodiment of the present invention; and

FIG. 29 is a schematic diagram illustrating a configuration of one or more photovoltaic strips, in accordance with another embodiment of the present invention.

### DETAILED DESCRIPTION

As used in the specification and claims, the singular forms “a”, “an” and “the” include plural references unless the context clearly dictates otherwise. For example, the term “a photovoltaic module” may include a plurality of photovoltaic modules unless the context clearly dictates otherwise. A term having “-containing” such as “metal-containing” contains a metal but is open to other substances, but need not contain any other substance other than a metal.

Embodiments of the present invention provide a method, system and apparatus for generating electricity from solar energy, and a method and system for manufacturing a photovoltaic module. In the description herein for embodiments of the present invention, numerous specific details are provided, such as examples of components and/or mechanisms, to provide a thorough understanding of embodiments of the present invention. One skilled in the relevant art will recognize, however, that an embodiment of the present invention can be practiced without one or more of the specific details, or with other apparatus, systems, assemblies, methods, components, materials, parts, and/or the like. In other instances, well-known structures, materials, or operations are not specifically shown or described in detail to avoid obscuring aspects of embodiments of the present invention.

### GLOSSARY

Photovoltaic module: A photovoltaic module is a packaged interconnected assembly of photovoltaic cells, which converts solar energy into electricity by the photovoltaic effect.
Integrated manner: In terms of the apparatus (photovoltaic module), it means that the electrically connected photovoltaic regions and the concentrator elements form an integrated and functional unit only at the module level. Any sub-part of the apparatus is not a functionally independent unit. In terms of the method of manufacturing in an integrated manner, it means that the assembly of the apparatus (photovoltaic module) consisting of photovoltaic regions, optical vees, and transparent member on the base substrate is carried out in one integrated sequence of operations without making functionally separate sub-units or sub-assemblies.
Base substrate: A base substrate is a term used to describe the base member of photovoltaic module on which photovoltaic strips are placed. The base substrate has an electrically insulated top surface.
Photovoltaic strip: A photovoltaic strip is a part of semiconductor wafer used in the fabrication of photovoltaic module.
Optical vee: An optical vee is a member with at least two surfaces arranged in the shape of ‘inverted-V’. Optionally, the optical vee includes a support element and a concentrating element overlying the support element.
Connector: A connector is member with shape such as to support the optical vee.
Polymeric material: A polymeric material is a substance composed of molecules with large molecular mass composed of repeating structural units, or monomers, connected by covalent chemical bonds.
Connecting space: Connecting space is the area between the adjacent connectors on the photovoltaic module.
Cavity: Cavity is three-dimensional region formed between adjacent optical vees and the photovoltaic strip that is placed between the adjacent optical vees.
Medium boundary: Medium boundary is a boundary between two mediums. For example, a medium boundary is formed at a boundary between glass and air.
Laminate: Laminate is an entire assembly of the photovoltaic strip, base substrate, optical vee and transparent member joined by the polymeric material.
Reflection-enhancing layer: Reflection-enhancing layer is a layer that enhances the reflectivity of a surface.
Transparent member: Transparent member is an optically clear member placed over the photovoltaic module to seal and protect the photovoltaic module from environmental damage.
Anti-reflective coating: Anti-reflective coating is a coating over the transparent member to reduce loss of solar energy incident on the photovoltaic module.
Dicer: A dicer is for dicing a semiconductor wafer to form the photovoltaic strips.
Snap-fit attaching unit: A snap-fit attaching unit is a unit for attaching the connectors to the base substrate.
Stringer: A stringer is for connecting the photovoltaic strips through one or more conductors.
Strip-arranger: A strip arranger is for arranging the photovoltaic strips over the base substrate.
Optical-vee placer: An optical-vee placer is for placing the optical vees in the spaces between the photovoltaic strips.
Moulder: A moulder is for molding the polymeric material to form the optical vee.
Depositer: A depositer is for depositing the reflective material over the optical vees to form the reflective layer or surface.
Tool: A tool is for machining solid blocks of the reflective material to form the optical vee.
Polisher: A polisher is for polishing surface of the reflective layer or surface.
Bending Unit: A bending unit is for bending a sheet/foil to form the optical vee.
Sandwiching Unit: A sandwiching unit is for sandwiching a foil of the reflective material between two plastic sheets to form a sandwiched foil.
Positioning unit: A positioning unit is for positioning the transparent member over the optical vees.
Sealing unit: A sealing unit is for sealing the transparent member with the base substrate.
Power-consuming unit: A power consuming unit is for consuming the power generated by the photovoltaic module. The power consuming unit may store the charge also.
AC Load: AC Load is a device that operates on Alternating Current (AC).
DC Load: DC Load is a device that operates on Direct Current (DC).
Charge controller: A charge controller controls the amount of charge consumed by the power consuming unit.
Inverter: An inverter converts the electricity from a first form to a second form. For example, it converts electricity from AC to DC or vice-versa.

Embodiments of the photovoltaic module include a base substrate (also referred as backpanel), for example, made of anodized aluminum for providing a support to the photovoltaic module. Connectors are attached to the base substrate. Connecting spaces are formed between the connectors. Photovoltaic cell strips are arranged in the connecting spaces over the base substrate in strings with series and/or parallel arrangement, such that electrical output is maximized. A plurality of transparent and hollow optical vees are placed over the base substrate. The optical vees are connected to the base substrate through the connectors.

Embodiments of the photovoltaic module include a base substrate (also referred as backpanel), for example, made of anodized aluminum for providing a support to the photovoltaic module. Connectors are attached to the base substrate. Connecting spaces are formed between the connectors. Photovoltaic cell strips are arranged in the connecting spaces over the base substrate in strings with series and/or parallel arrangement, such that electrical output is maximized. A plurality of reflecting optical vees are placed over the base substrate. The optical vees are connected to the base substrate through the connectors. The optical vees can be solid (like a glass prism) or hollow inside (like two mirrors forming a vee) with a reflective metal coating on the inside walls of the hollow optical vees. An optically clear, low iron content glass cover sheet is generally placed on the optical vees. The cover glass and the aluminum backpanel are sealed at their edges using silicon to form an enclosed photovoltaic module that seals the inside of the module from moisture.

The photovoltaic module includes a base substrate for providing support to the photovoltaic module. A plurality of connectors is attached to the base substrate. A connecting space is formed between the adjacent connectors. One or more photovoltaic strips are arranged in the connecting spaces over the base substrate. The photovoltaic strips are electrically connected in a predefined manner. The predefined manner may, for example, be a series and/or parallel arrangement, such that electrical output is maximized.

In an embodiment of the present invention, the photovoltaic strips may be formed by dicing a semiconductor wafer. In another example, the photovoltaic strips may be circular or arc-like in shape, and may be arranged in the form of concentric circles. In another example, the photovoltaic strips may be rectangular in shape, and may be arranged substantially parallel to each other. The photovoltaic strips may also be square, triangular, or any other shape, in accordance with a desired configuration. The photovoltaic strips are connected through one or more conductors in series and/or parallel.

A plurality of optical vees is connected to the base substrate through the connectors. The optical vees are capable of concentrating the solar energy over the photovoltaic strips. The optical vees are inverted-V-shaped in cross-section, in accordance with an embodiment of the present invention. In accordance with another embodiment of the present invention, the optical vees are compound-parabolic-shaped in cross-section. The optical vees have a reflective layer or surface, such that sun rays incident on the reflective layer or surface are reflected towards the photovoltaic strips. When the reflected sun rays fall on the photovoltaic strips, electricity is generated by the photoelectric effect. These optical vees may, for example, be made of a glass, a plastic, polymeric materials, ethyl vinyl acetate (EVA), thermoplastic poly-urethane (TPU), poly vinyl butyral (PVB), a silicone, an acrylic, a polycarbonate, a metal, a metallic alloy, a metal compound, and a ceramic. In accordance with an embodiment of the present invention, the optical vees comprise a reflection-enhancing layer or surface to enhance the reflectivity of the optical vees.

In an embodiment of the present invention, the optical vees are formed by polishing surfaces of a prism of a reflective material. In this case, the optical vees are solid. In another embodiment of the present invention, the optical vees are formed by polishing a sheet of a reflective material, which may be bent in a desired shape of the optical vees. In such a case, the optical vees are hollow and the optical vees may, for example, be V-shaped or triangular in cross-section. In yet another embodiment of the present invention, the optical vees are made of a foil of a reflective material sandwiched between two moldable sheets. The sandwiched foil is bent in a desired shape of the optical vees. As the mouldable are electrically non-conductive, the optical vees can be placed over the conductors. In such a case, the optical vees are hollow and the optical vees may, for example, be V-shaped or triangular in cross-section. In still another embodiment of the present invention, the reflective layer or surface is formed by coating the optical vees with a reflective material.

A transparent member is positioned over the optical vees. The transparent member protects the photovoltaic strips and the optical vees from environmental damage. In accordance with an embodiment of the present invention, the transparent member is sealed with the base substrate. In accordance with an embodiment of the present invention, the base substrate, the connectors, the photovoltaic strips, the optical vees and the transparent member form the photovoltaic module in an integrated manner. In accordance with an embodiment of the present invention, the transparent member is coated with an anti-reflective coating to reduce loss of solar energy incident on the photovoltaic module.

The acceptance angle of the photovoltaic module is chosen, such that rays within the angular limit normal to the module may be reflected towards the photovoltaic strips with minimal optical losses. Tracking mechanisms may be used to change the position of the photovoltaic module, in order to keep the rays normally incident upon the photovoltaic module while the sun moves across the sky. This further enhances the power output of the photovoltaic module.

The photovoltaic module can be used in various applications. For example, an array of photovoltaic modules may be used to generate electricity on a large scale for grid power supply. In another example, photovoltaic modules may be used to generate electricity on a small scale for home/office use. Alternatively, photovoltaic modules may be used to generate electricity for stand-alone electrical devices, such as automobiles and spacecraft. Details of these applications have been provided in conjunction with drawings below.

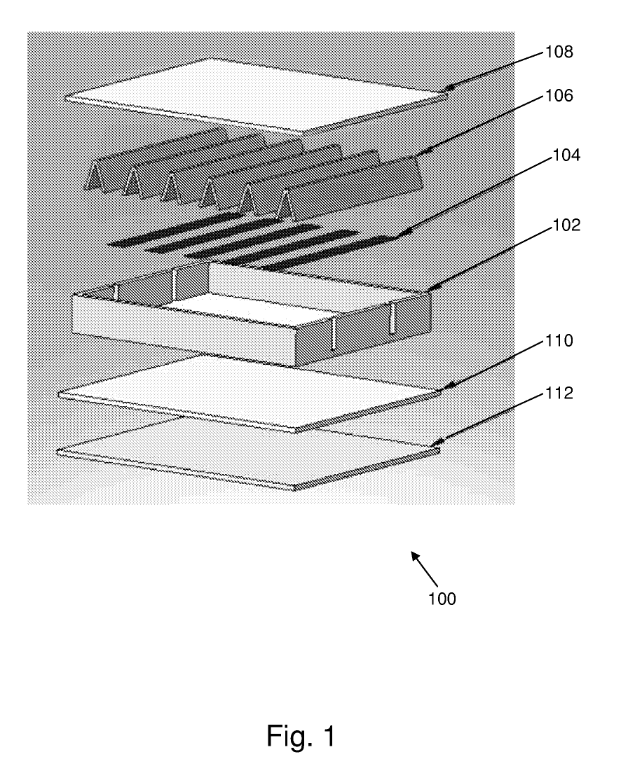

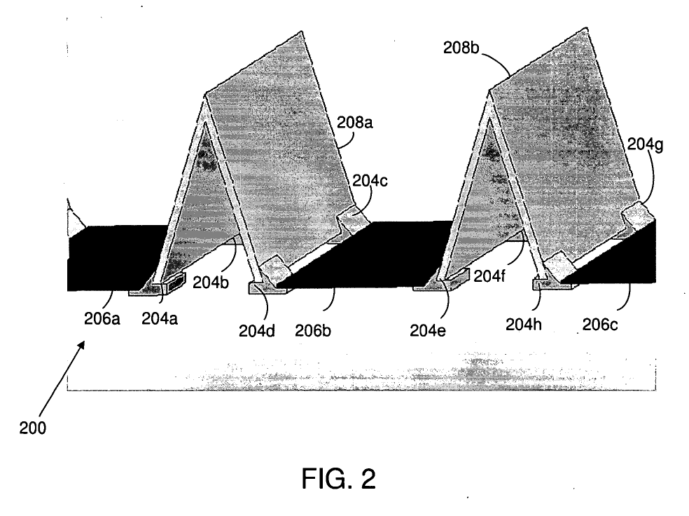

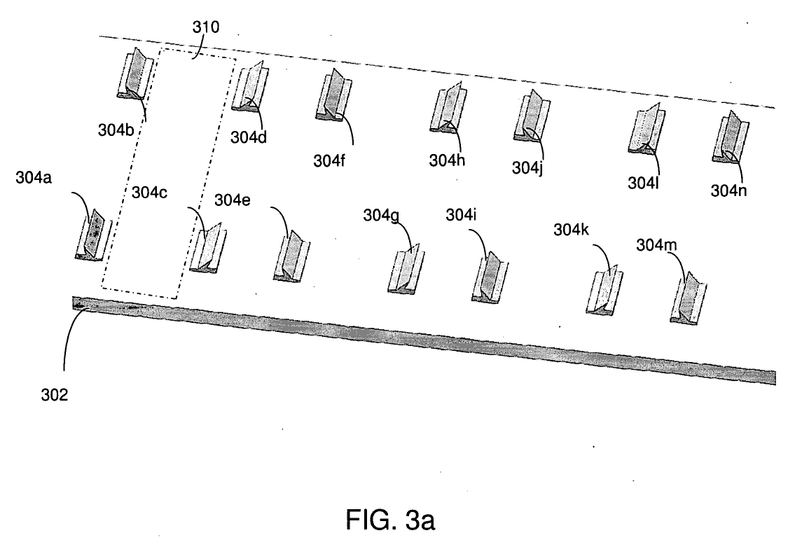

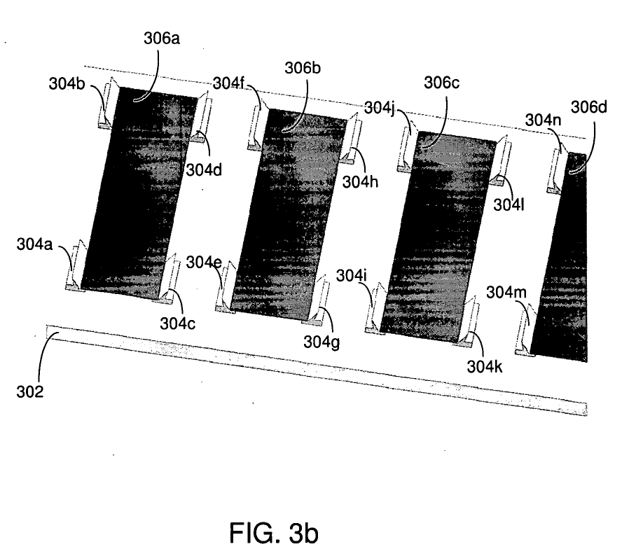

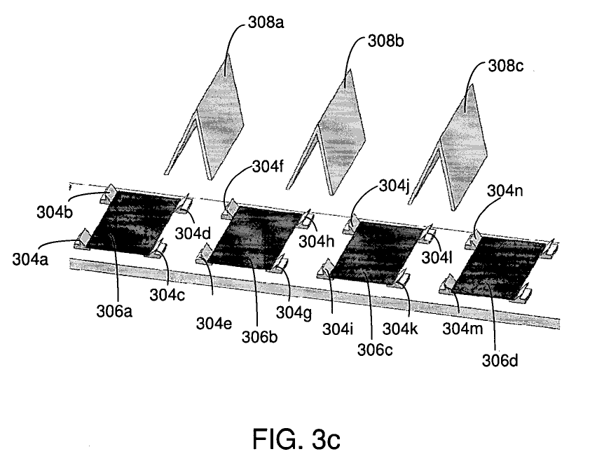

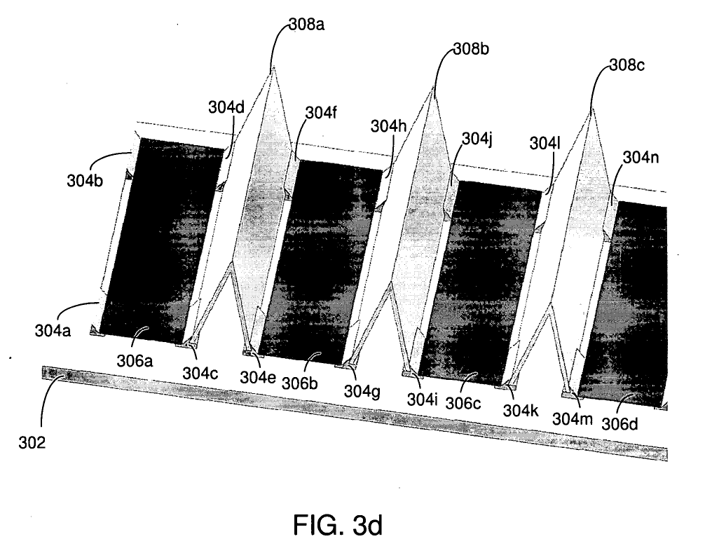

FIG. 1 illustrates a blown-up view of a photovoltaic module 100, in accordance with an embodiment of the present invention. Photovoltaic module 100 includes a base substrate 102, one or more photovoltaic strips 104, a plurality of optical vees 106, a transparent member 108, a laminate 110 and a supporting substrate 112. Further, base substrate 102 includes a plurality of connectors (not shown in FIG. 1) for connecting the optical vees 106 with base substrate 102. Details corresponding to the connectors have been described in conjunction with FIGS. 2, 3a-d, 4, 5a-d, 6, 7a-d and 8a-b.

Base substrate 102 provides a support for photovoltaic module 100. With reference to FIG. 1, base substrate 102 is rectangular in shape. Base substrate 102 can be made of any material that is tolerant to moisture, Ultra Violet (UV) radiation, abrasion, and natural temperature variations. Examples of such materials include, but not limited to, aluminium, steel, plastics and suitable polycarbonates. In addition, base substrate 102 may, for example, be made of plastics with metal coating or plastics with high thermal conductivity fillers. Examples of such fillers include, but are not limited to, boron nitride (BN), aluminium oxide, (Al₂O₃), and metals. Base substrate 102 has an electrically insulated top surface. For example, base substrate 102 may be coated with a layer of electrically insulating material, such as anodized material.

The connectors are attached to the base substrate 102. Connectors may be, for example, attached to the base substrate in parallel. A plurality of connecting spaces is formed between the connectors. The connectors may be electrically insulated elements or may be elements with coating of electrical insulating materials. The connectors may be made of any material that is electrically insulator, tolerant to moisture, Ultra Violet (UV) radiation, abrasion, and natural temperature variations. Examples of such materials include, but not limited to, aluminium, steel, plastics and suitable polycarbonates. In addition, the connectors may, for example, be made of plastics with metal coating or plastics with high thermal conductivity fillers. Examples of such fillers include, but are not limited to, boron nitride (BN), aluminium oxide, (Al₂O₃), and metals. Various methods may be used to attach connectors to the base substrate. The connectors may be attached to the base substrate using an adhesive, nut and bolt mechanism or they can be welded or soldered with the base substrate. In various embodiments, connectors may be of various shape and size. In an embodiment of the present invention, the connectors are elongated Z-shaped elements. In another embodiment of the present invention, the connectors are angular elements. In yet another embodiment, the connectors are flexible elements. Details of various types of connectors have been explained in conjunction with FIGS. 2, 3a-d, 4, 5a-d, 6, 7a-d and 8a-b.

Photovoltaic strips 104 are arranged in the connecting spaces over base substrate 102. With reference to FIG. 1, photovoltaic strips 104 are rectangular in shape and are arranged parallel to each other. Photovoltaic strips 104 are made of a semiconductor material. Examples of semiconductors include, but are not limited to, monocrystalline silicon (c-Si), polycrystalline or multicrystalline silicon (poly-Si or mc-Si), ribbon silicon, cadmium telluride (CdTe), copper-indium diselenide (CuInSe₂), combinations of III-V and II-VI elements in the periodic table that have photovoltaic effect, copper indium/gallium diselenide (CIGS), gallium arsenide (GaAs), germanium (Ge), gallium indium phosphide (GaInP₂), organic semiconductors such as polymers and small-molecule compounds like polyphenylene vinylene, copper phthalocyanine and carbon fullerenes, amorphous silicon (a-Si or a-Si:H), protocrystalline silicon, and nanocrystalline silicon (nc-Si or nc-Si:H). Photovoltaic strips 104 are electrically connected through one or more conductors in a predefined manner. The predefined manner, for example, may be series and/or parallel, such that the output electrical energy is at its maximum. Examples of conductors may include, but are not limited to, metallic strips, such as copper or aluminum strips. When electromagnetic radiation falls over photovoltaic strips 104, electron-hole pairs are separated by some means before they recombine giving rise to a voltage. When a load is connected across the two electrodes, the generated voltage produces a current producing electrical energy.

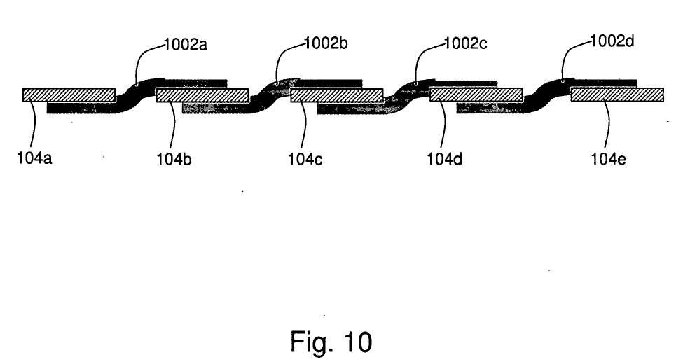

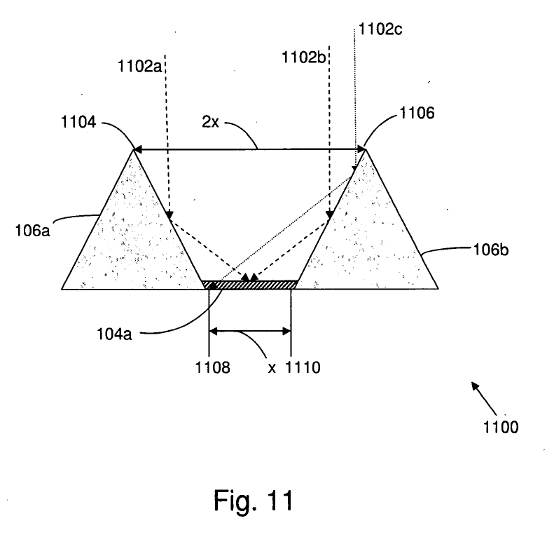

With reference to FIG. 1, optical vees 106 are connected to base substrate 102 through the connectors, not shown in the FIG. 1. The connectors firmly hold optical vees 106 with base substrate 102. Further, the connectors enable the ease of connecting optical vees 106 to base substrate 102. Optical vees 106 concentrate the electromagnetic radiation over photovoltaic strips 104. The level of concentration may be varied depending on the shape and size of optical vees 106. Details of various levels of concentration have been provided in conjunction with FIGS. 10 and 11.

Transparent member 108 is positioned over optical vees 106. Transparent member 108 protects optical vees 106 and photovoltaic strips 104 from environmental damage, while allowing electromagnetic radiation falling on its surface to pass through. With reference to FIG. 1, transparent member 108 is flat rectangular in shape. In other cases, transparent member 108 may have any desired shape, such as a curved shape. The refractive index of transparent member 108 can be varied, while minimizing the reflectivity of transparent member 108, to increase the efficiency of concentration. Transparent member 108 is coated with an anti-reflective coating on its top and bottom surfaces, so that no reflection occurs at medium boundaries between air and transparent member 108.

In accordance with an embodiment of the present invention, laminate 110 is formed by a laminate material to encapsulate photovoltaic strips 104 and optical vees 106. Laminate 110 holds photovoltaic module 100 and its components together, and protects photovoltaic module 100 against moisture, abrasion, and natural temperature variations. The process of lamination is performed at a prescribed temperature and/or pressure in a vacuum environment using a laminator. The vacuum environment ensures that no air bubbles are formed within the laminate. In order to avoid heat sinking during lamination, supporting substrate 112 is used as a heat barrier, and removed later.

The laminate material can be any material that is tolerant to moisture, UV radiation, abrasion, and natural temperature variations. Examples of the laminate material include, but are not limited to, EVA, silicone and other synthetic resins.

As the seal at the edge of photovoltaic module 100 so formed may remain non-hermetic, an additional step of framing photovoltaic module 100 may be performed. This can be accomplished by mechanically attaching a frame to laminate 110.

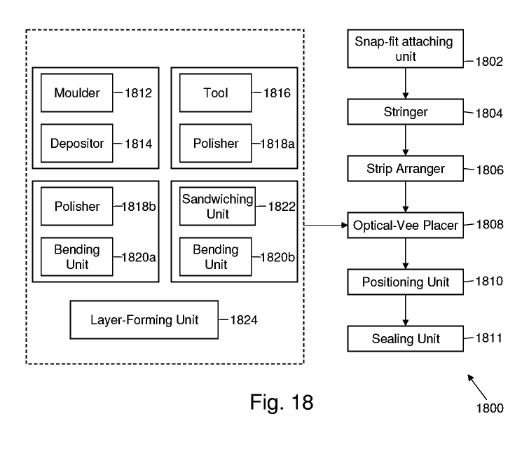

In an embodiment of the present invention, the fabrication of photovoltaic module 100 is done by using a high speed robotic assembly. The robotic assembly includes one or more robotic arms, which are employed for performing various processes during the fabrication. In one example, a robotic arm may be used to attach connectors to the base substrate 102. In another example, another robotic arm may be used to arrange photovoltaic strips 104 in the connecting spaces over base substrate 102. In another example, the placement and connection of optical vees 106 to base substrate may be done with yet another robotic arm. In various embodiments of the present invention, one robotic arm may be used to perform all the above functions. Details of the system for manufacturing photovoltaic module 100 have been explained in detail in conjunction with FIG. 18. The processes of wire bonding and die attachment in fabrication of photovoltaic module 100 may also be performed with the robotic arms.

It is to be understood that the specific designation for photovoltaic module 100 and its components is for the convenience of the reader and is not to be construed as limiting photovoltaic module 100 and its components to a specific number, size, shape, type, material, or arrangement.

FIG. 2 illustrates an arrangement 200 of a plurality of optical vees over a base substrate through a plurality of connectors, in accordance with an embodiment of the present invention. Arrangement 200 includes a plurality of connectors, such as a connector 204a, a connector 204b, a connector 204c, a connector 204d, a connector 204e, a connector 204f, a connector 204g and a connector 204h, one or more photovoltaic strips, such as a photovoltaic strip 206a, a photovoltaic strip 206b and a photovoltaic strip 206c, and a plurality of optical vees, such as an optical vee 208a and an optical vee 208b. With reference to FIG. 2, connectors 204a, 204b, 204c, 204d, 204e, 204f, 204g and 204h are angular elements.

Arrangement 200 has been explained in detail in conjunction with FIGS. 3a, 3b, 3c and 3d.

FIGS. 3a, 3b, 3c, and 3d illustrate various stages of formation of arrangement 200, in accordance with an embodiment the present invention. FIG. 3a illustrates an arrangement of a plurality of connectors 304a-n on a base substrate 302. Connectors 304a-n are angular elements. The shape of the angular elements is designed in such a way that the upper extending portions of connectors 304a-n are designed to receive one or more optical vees.

Connectors 304a-n may be attached to base substrate 302 in various ways. For example, connectors 304a-n may be attached to base substrate 302 using adhesives, welding, soldering, screws, or nut and bolts. Connectors may be attached to base substrate 302 in various possible layouts. With reference to FIG. 3a, connectors 304a-n are attached to base substrate 302 in a linear layout. Alternatively, connectors 304a-n may be attached to base substrate 302 in a circular layout. Connectors 304a-n are attached with base substrate 302 in such a manner that a plurality of connecting spaces is formed between connectors 304a-n. For example, connectors 304a, 304b and connectors 304c, 304d form a connecting space 310a on base substrate 302. Similar spaces are formed between other connectors.

FIG. 3b illustrates placement of one or more photovoltaic strips in connecting spaces between conductors 304a-n. With reference to FIG. 3b, photovoltaic strips 306a-d are arranged in the connecting spaces over base substrate 302. Photovoltaic strips 306a-d may, for example, be picked and placed by a strip arranger. The photovoltaic strips are electrically connected through conductors in a predefined manner, for example, in series and/or parallel arrangement. Optical vees 308a-d are slided through connectors 304a-n over base substrate 302, as shown in FIG. 3c. Consequently, optical vees 308a-c are connected to base substrate 302 through connectors 304a-n, as shown in FIG. 3d.

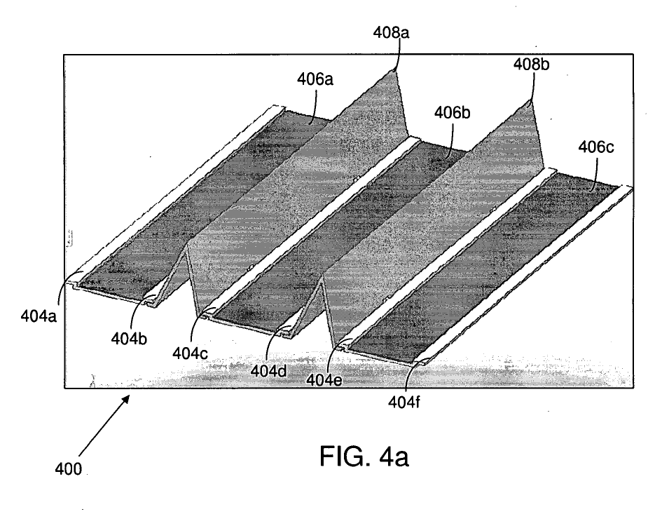

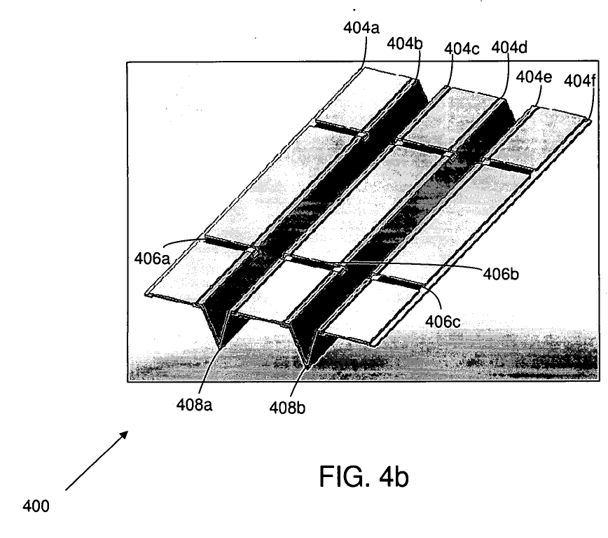

FIGS. 4a and 4b illustrate an arrangement 400 of a plurality of optical vees over a base substrate through a plurality of connectors, in accordance with another embodiment of the present invention. Arrangement 400 includes a plurality of connectors 404a-f, such as a connector 404a, a connector 404b, a connector 404c, a connector 404d, a connector 404e and a connector 404f, photovoltaic strips 406a-c, and a plurality of optical vees, such as an optical vee 408a and an optical vee 408b. With reference to FIGS. 4a and 4b, connectors 404a-f are Z-shaped elements.

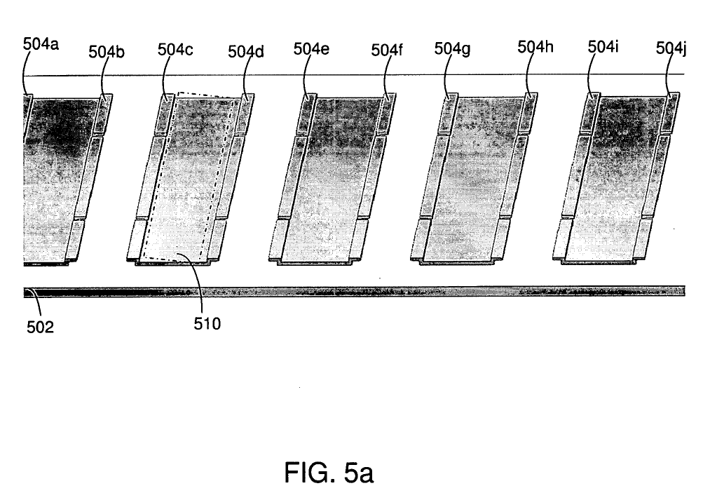

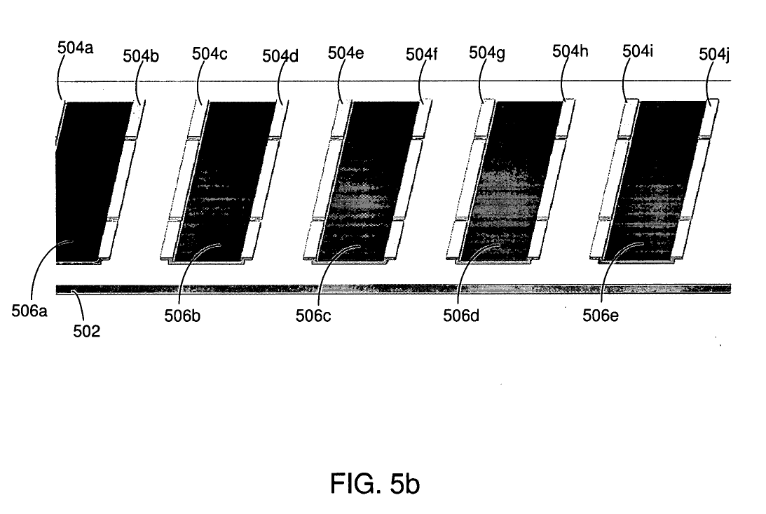

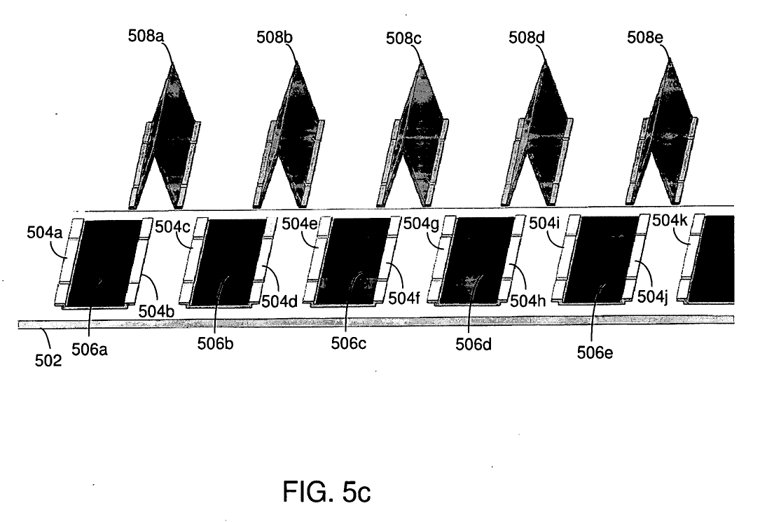

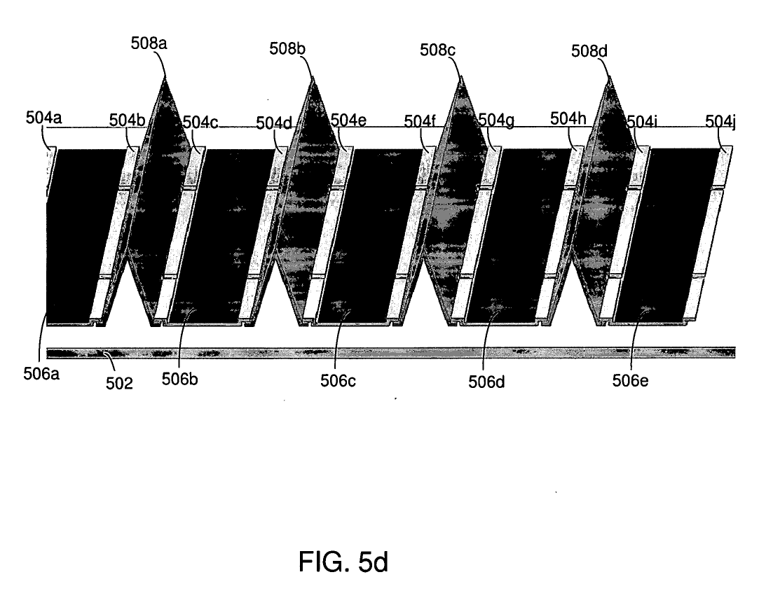

Arrangement 400 has been explained in detail in conjunction with FIGS. 5a, 5b, 5c and 5d.

FIGS. 5a, 5b, 5c and 5d illustrate various stages of formation of arrangement 500, in accordance with another embodiment of the present invention. In FIG. 5a, connectors 504a-j are elongated Z-shaped elements. Connectors 504a-j are attached with a base substrate 502 in such a manner that a plurality of connecting spaces is formed between connectors 504a-j. For example, connectors 504b and 504c form a connecting space 510a on base substrate 502. Similar connecting spaces are formed between other connectors.

Connectors 504a-j may be attached to base substrate 502 in various ways. As described earlier, connectors 504a-j may be attached to base substrate 502 using adhesives, welding, soldering, screws, or nut and bolts. Connectors 504a-j may be attached to base substrate 502 in various possible layouts. With reference to FIG. 5a, connectors 504a-j are attached to base substrate 502 in a linear layout. Alternatively, connectors 504a-j may be attached to base substrate 502 in a circular layout. Photovoltaic strips 506a-e are arranged in the connecting spaces between connectors 504a-j over base substrate 502, as shown in FIG. 5b. Photovoltaic strips 506a-e may be picked and placed by a strip arranger. Photovoltaic strips 3006a-e may be electrically connected through conductors in predefined manner, for example, in series and/or parallel arrangement. Optical vees 508a-e are slided through connectors 504a-j from one side, as shown in FIG. 5c. Optical vees 508a-e include one or more extended portions extending outwards of optical vees 508a-e. As shown in FIG. 5d, optical vees 508a-e are slided through connectors 504a-j and are fixed with base substrate 502.

In accordance with an embodiment of the present invention, adjacent connectors are combined together to form one connector. With reference to FIGS. 5a, 5b, 5c and 5d, connectors 504a and 504b may be combined together to form one connector, connectors 504c and 504d may be combined together to form one connector, and so on.

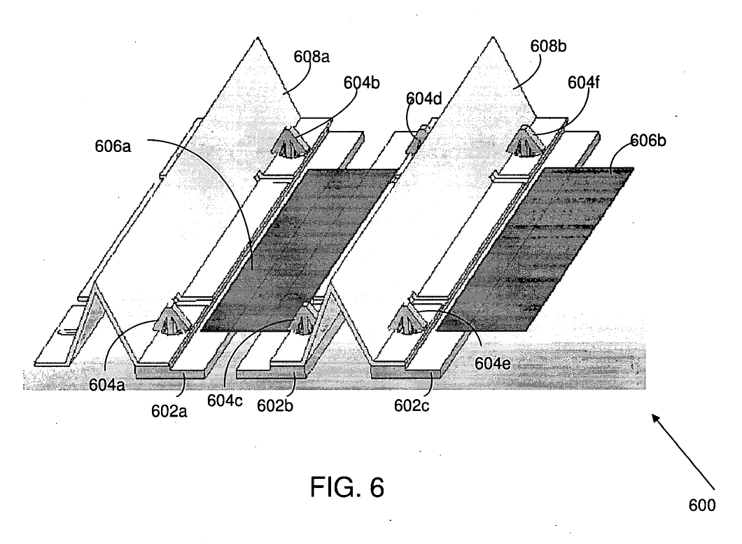

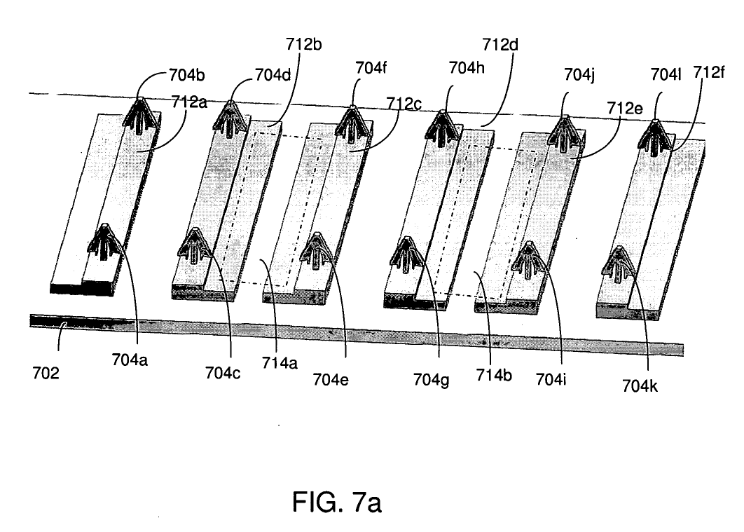

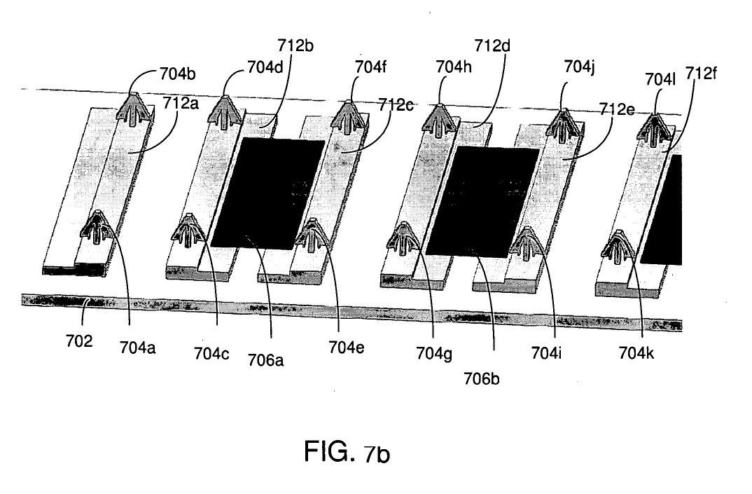

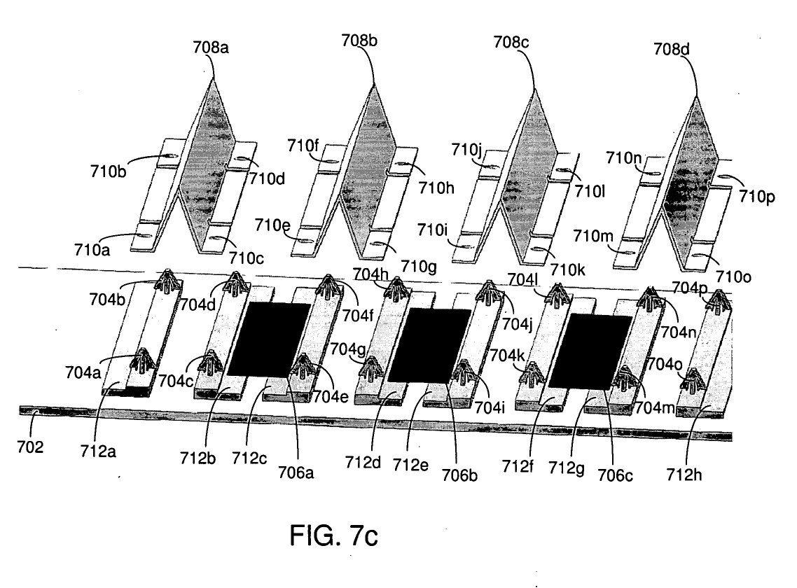

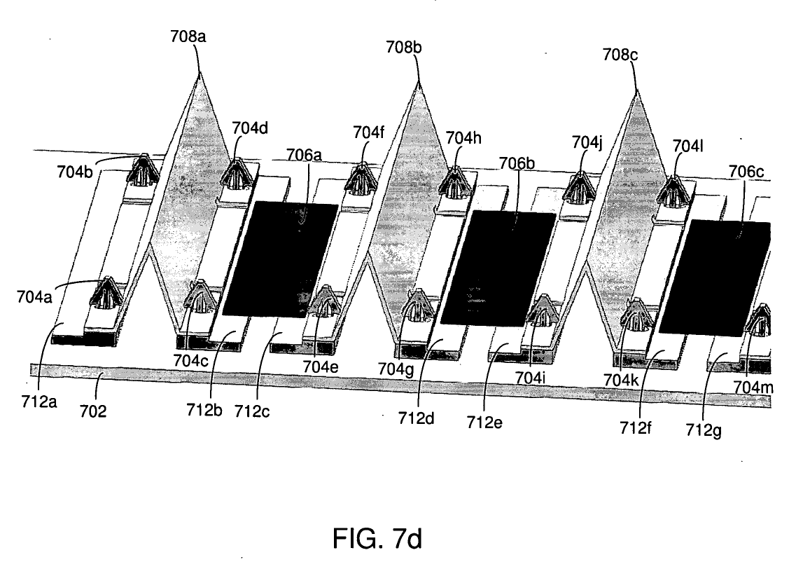

FIG. 6 illustrates an arrangement 600 of the optical vees to connectors 604a-f, in accordance with another embodiment of the present invention. Arrangement 600 includes a plurality of connectors 602a-c, a plurality of flexible elements 604a-f and a plurality of optical vees 608a-b. Connectors 602a and 602b are attached with a base substrate (not shown in the figure). In an embodiment of the present invention, flexible elements 604a-f are attached with connectors 602a and 502b. Combination of connectors 602a-b and flexible elements 604a-f may be formed as an integrated connector. Connectors 602a-b and flexible elements 604a-f may be electrically insulated elements or may be elements with coating of electrical insulating materials. They may be made of a material that is electrically insulator, tolerant to moisture, Ultra Violet (UV) radiation, abrasion, and natural temperature variations. Examples of such materials include, but not limited to, aluminium, steel, plastics and suitable polycarbonates. In addition, the connectors may, for example, be made of plastics with metal coating or plastics with high thermal conductivity fillers. Further, flexible elements 604a-f may be made of flexible materials, such as rubber, plastic, polymer and the like. Details of arrangement 600 have been explained in conjunction with FIG. 7a-d.

FIGS. 7a, 7b, 7c, 7d illustrate various stages of arrangement 700, in accordance with another embodiment the present invention. With reference to FIG. 7a, arrangement 700 includes a base substrate 702, a plurality of connectors 712a-f, and a plurality of flexible elements 704a-1. Connectors 712a-f are attached with base substrate 702. Connectors 712a-f may be attached to the base substrate using an adhesive, nut and bolt mechanism or they can be welded or soldered with the base substrate. Connectors 712a-f are attached to base substrate 702 in a rectangular layout. Alternatively, connectors 712 may be attached to base substrate 702 in a circular layout. Further, flexible elements 704a-1 are attached with connectors 712a-f. In an embodiment of the present invention, flexible elements 704a-1 and connectors 712a-f may together form integrated connectors. For example, flexible element 704a and 704b may be integrated with connector 712a. Connectors 712a-f are attached with base substrate 702 in such a manner that a plurality of connecting spaces 714a-b are formed between connectors 712a-f.

With reference to FIG. 7b, one or more photovoltaic strips 706a and 706b are arranged in the connecting spaces 714a-b over base substrate 702. Photovoltaic strips 706a and 706b may be electrically connected through one or more conductors in predefined manner, for example, in series and/or parallel arrangement, such that electrical output is maximized.

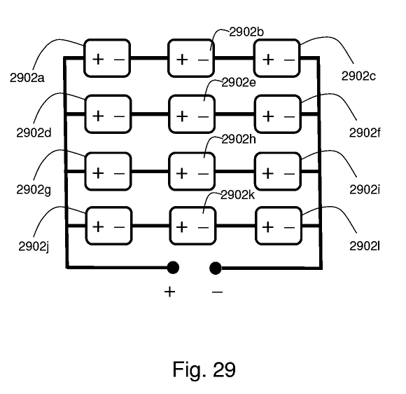

With reference to FIG. 7c, a plurality of optical vees 708 a-d are placed over base substrate 702. Optical vees 708 a-d may include one or more extended portions extending outwards of the optical vees 708a-d. The extended portion of optical vees 708a-d includes a plurality of holes 710a-n. The holes 710a-n enables optical vees 708a-d to connect with base substrate 702 through flexible elements 704a-n and connectors 712a-f. In an embodiment of the present invention, flexible elements 714a-n are inserted in to holes 710a-n. The diameter of holes 710a-n is smaller than the diameter of flexible elements 714a-n. For example, flexible elements 704a-n expands after getting inserted into holes 710a-n due to their flexible nature. This enables the flexible elements 704a-n to lock with holes 710a-n. This in turn connects optical vees 708a-d with base substrate 702. Optical vees 708a-d are connected with base substrate 702, as shown in FIG. 29d.

In various embodiments of the present invention, shape of flexible elements 714a-n may be designed in different manner. The shape of flexible elements may be in the form of an arrow, T-shape and the like.

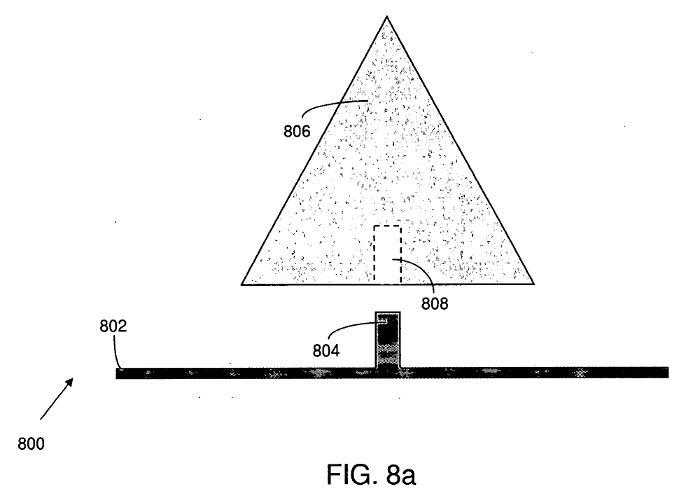

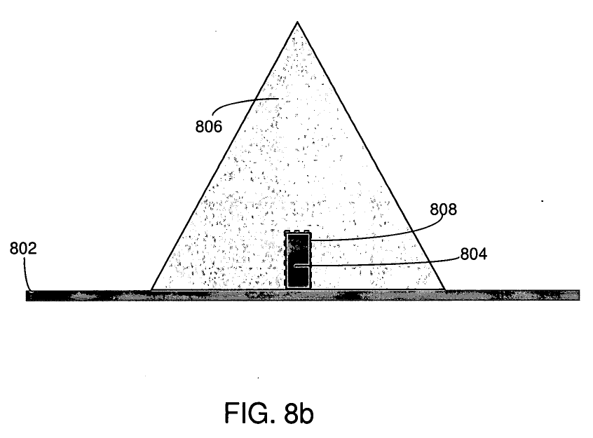

FIGS. 8a and 8b illustrate various stages of arrangement 800, in accordance with an embodiment of the present invention. Arrangement 800 includes a base substrate 802, one a connector 804 and an optical vee 806. Optical vee 806 includes a groove 808 for receiving connector 804. In an embodiment of the present invention, groove 808 may be in the form of a hole. Optical vee 806 is connected to the base substrate 802 through the connector 804. In an embodiment of the present invention, connector 804 is present in the form of a stud.

In various embodiments of the present invention, connector 804 may be made of a material, such as aluminium, steel, plastics or suitable polycarbonates. In addition, the connector 804 may, for example, be made of plastics with metal coating or plastics with high thermal conductivity fillers. Connector 804 may also be made of a flexible material.

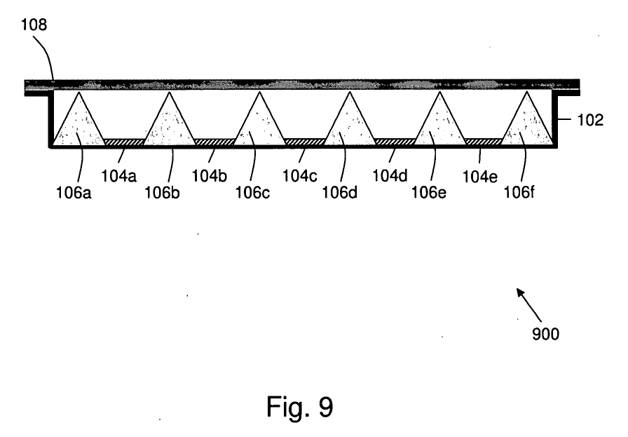

FIG. 9 illustrates a cross-sectional view of photovoltaic module 100, in accordance with an embodiment of the present invention. In FIG. 9, photovoltaic strips 104 are shown as a photovoltaic strip 104a, a photovoltaic strip 104b, a photovoltaic strip 104c, a photovoltaic strip 104d, and a photovoltaic strip 104e. Optical vees 106 are shown as an optical vee 106a, an optical vee 106b, an optical vee 106c, an optical vee 106d, an optical vee 106e, and an optical vee 106f. Optical vees 106 are connected with base substrate 102 through one or more connectors (not shown in figure). Optical vees 106 are connected with the base substrate 102 as described in FIGS. 2, 3a-d, 4, 5a-d, 6, 7a-d and 8a-b. With reference to FIG. 9, optical vee 106a and optical vee 106b concentrate solar energy towards photovoltaic strip 104a, optical vee 106b and optical vee 106c concentrate solar energy towards photovoltaic strip 104b, and so on. With reference to FIG. 9, optical vees 106 are solid. Transparent member 108 is coated with an anti-reflective coating and is placed over base substrate 102 enclosing photovoltaic strip 104a, photovoltaic strip 104b, photovoltaic strip 104c, photovoltaic strip 104d, photovoltaic strip 104e, optical vee 106a, optical vee 106b, optical vee 106c, optical vee 106d, optical vee 106e, and optical vee 106f. It should be noted that the enclosure of base substrate 102 is not limited to the number of elements shown in the figure.

A single photovoltaic strip and a single optical vee are collectively termed as a ‘low concentrator unit’. A plurality of such low concentrator units may be combined together to form a photovoltaic module, in accordance with an embodiment of the present invention.

FIG. 10 illustrates how photovoltaic strips 104 are connected through a plurality of conductors, in accordance with an embodiment of the present invention. With reference to FIG. 10, photovoltaic strips 104 are connected in series. In such a configuration, the p-side of photovoltaic strip 104a is connected to the n-side of photovoltaic strip 104b using a conductor 1002a, the p-side of photovoltaic strip 104b is connected to the n-side of photovoltaic strip 104c using a conductor 1002b, the p-side of photovoltaic strip 104c is connected to the n-side of photovoltaic strip 104d using a conductor 1002c, and the p-side of photovoltaic strip 104d is connected to the n-side of photovoltaic strip 104e using a conductor 1002d.

FIG. 11 illustrates an arrangement 1100 of photovoltaic strip 104a between solid optical vees 106a and 306b, in accordance with an embodiment of the present invention. With reference to FIG. 11, optical vees 106 are solid. Optical vees 106 are formed by machining and polishing solid blocks of a reflective material, such as a metal, metallic alloy, or a metal compound. Examples of such reflective material include, but are not limited to, aluminum, silver, nickel, and steel. As described earlier, photovoltaic strips 104a are made of a semi-conductor material. Photovoltaic strip 104a is placed in between optical vee 106a and optical vee 106b, such that gaps are left between optical vee 106a and photovoltaic strip 104a, and between photovoltaic strip 104a and optical vee 106b. These gaps are left to avoid short circuiting between optical vees 106 and photovoltaic strips 104.

A ray 1102a, incident on a side of optical vee 106a, undergoes reflection and falls over photovoltaic strip 104a. Similarly, a ray 1102b, incident on a side of optical vee 106b, undergoes reflection and falls over photovoltaic strip 104a. However, a ray 1102c, incident on the side of optical vee 106b, undergoes reflection and falls away from photovoltaic strip 104a. In order to concentrate such a ray over photovoltaic strip 104a, the upper portion of the sides of optical vees 106 may be curved in as a concave. This reduces loss of solar energy.

An entry area, formed between an upper end 1104 of optical vee 106a and an upper end 1106 of optical vee 106b, has a length of ‘2x’ units. An exit area, formed between a lower end 1108 of optical vee 106a and a lower end 1110 of optical vee 106b, has a length of ‘x’ units. The entry area is defined as an area through which rays enter, while the exit area is defined as an area through which the rays exit towards photovoltaic strips 104. The level of concentration is measured by the ratio of the entry area and the exit area. With reference to FIG. 11, the level of concentration is equal to 2. The level of concentration may vary between 1.5 and 5. Since the power output of photovoltaic module 100 depends on the level of concentration, the power output doubles.

As mentioned above, the level of concentration may also be varied by varying the shape and size of optical vees 106. Heat sinkers and fin radiators may be used to avoid heat sinking in case of higher levels of concentration.

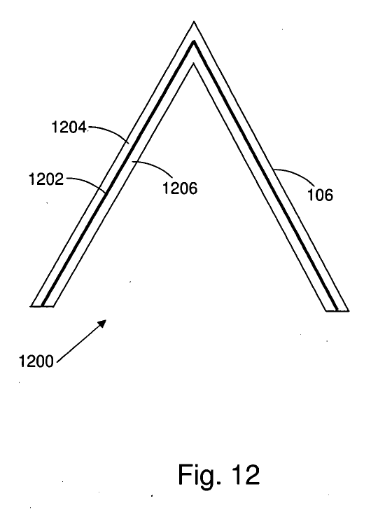

FIG. 12 illustrates an optical vee 1200, in accordance with yet another embodiment of the present invention. Optical vee 1200 is made of a foil 1202 of a reflective material sandwiched between two mouldable sheets 1204 and 1206. Sandwiched foil 1202 is bent to form an inverted-V-shape in cross-section. In such a case, optical vee 1200 is hollow in cross-section. As the outer layers of sandwiched foil 1202 are electrically insulated, optical vees 1200 made of such sandwiched foil may be placed in contact with photovoltaic strips 104. No short-circuiting occurs in such an arrangement.

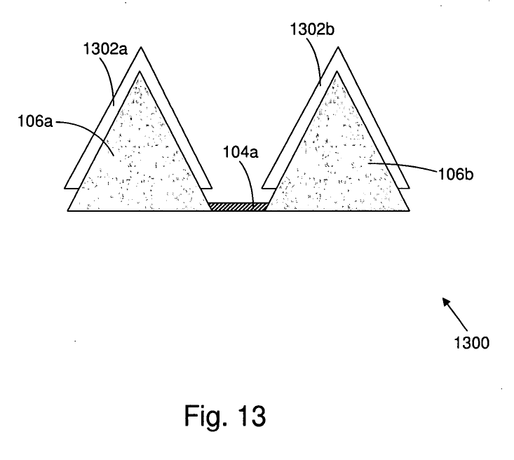

FIG. 13 illustrates an arrangement 1300 of photovoltaic strip 104a between solid optical vees 106a and 106b, in accordance with still another embodiment of the present invention. With reference to FIG. 13, optical vees 106 are solid. Optical vees 106 may, for example, be made of a glass, a plastic, EVA, silicone, TPU, an acrylic, a polycarbonate, a metal, an metallic alloy and a ceramic. Optical vee 106a and optical vee 106b are coated with a reflective layer or surface 1302a and a reflective layer or surface 1302b, respectively. Reflective layer or surface 1302a and reflective layer or surface 1302b may, for example, be made of reflective materials, such as aluminium, silver, nickel or other suitable metals, metallic alloys, and metal compounds.

With reference to FIG. 13, photovoltaic strip 104a is placed in between optical vee 106a and optical vee 106b, such that no gaps are left between optical vee 106a and photovoltaic strip 104a and between optical vee 106b and photovoltaic strip 104a. While reflective layer or surface 1302a and reflective layer or surface 1302b do not touch photovoltaic strip 104a, so as to avoid short circuiting between them.

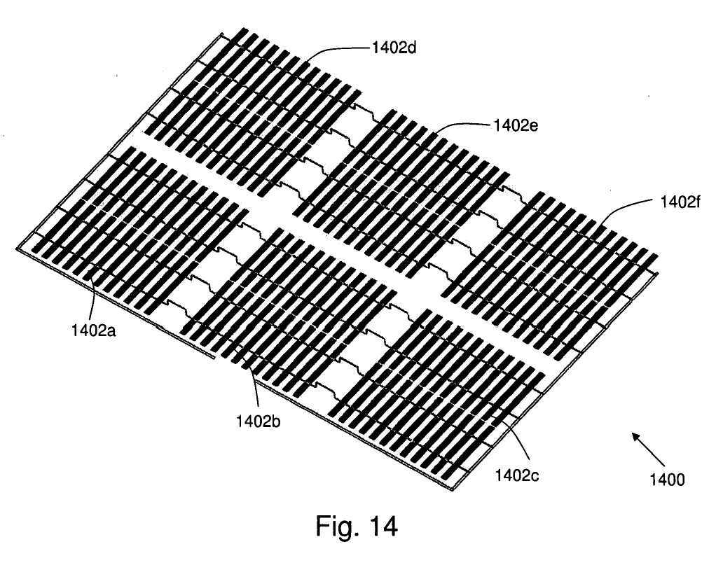

FIG. 14 is a perspective view of a string configuration 1400 of photovoltaic strips, in accordance with an embodiment of the present invention. A string 1402a, a string 1402b, a string 1402c, a string 1402d, a string 1402e and a string 1402f are formed by stringing one or more photovoltaic strips in series. String 1402a, string 1402b and string 1402c are combined in series. Similarly, string 1402d, string 1402e and string 1402f are combined in series. These two series configurations are then combined in parallel. String configuration 1400 is arranged over a base substrate, in accordance with an embodiment of the present invention.

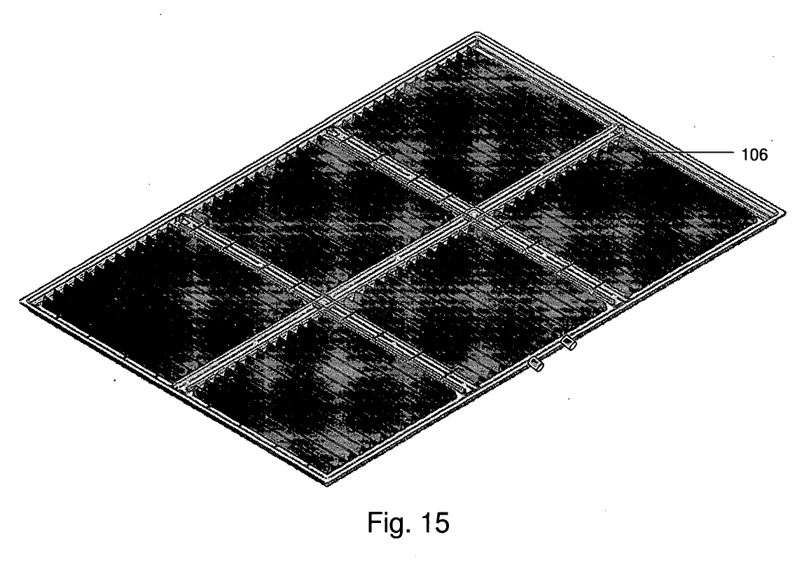

FIG. 15 is a perspective view illustrating optical vees 106 placed with string configuration 1400, in accordance with an embodiment of the present invention. Optical vees 106 are placed in between the connecting spaces of the connectors alternatively.

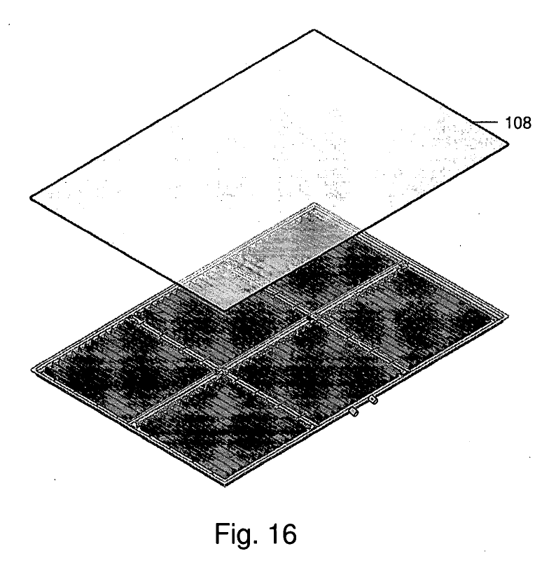

FIG. 16 is a perspective view illustrating a lay-up of a transparent member 108 over optical vees 106, in accordance with an embodiment of the present invention.

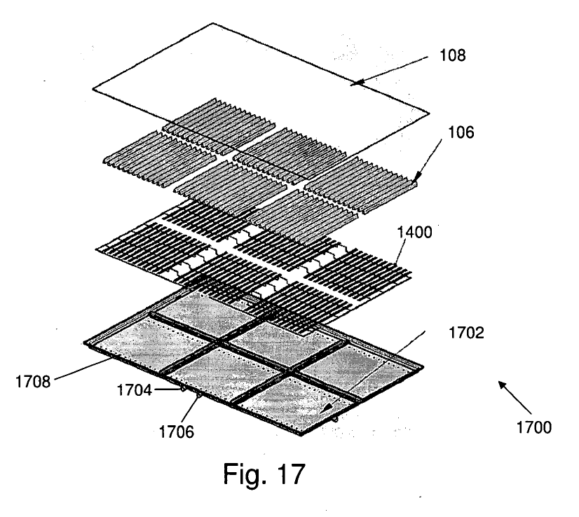

FIG. 17 is a blown-up view of a photovoltaic module 1700, in accordance with an embodiment of the present invention. With reference to FIG. 17, string configuration 1400 is arranged over a base substrate 1702. Base substrate 102 includes a plurality of connectors 1708. A plurality of connecting spaces is formed between connectors 1708. Optical vees 106 are aligned and placed over the connectors 1708. Connectors 1108 connect optical vees 106 with base substrate 102. Further, photovoltaic strips of string configuration 1400 are placed in the connecting spaces. Transparent member 1002 is positioned over optical vees 106.

Base substrate 102 includes a positive terminal 1704 and a negative terminal 1706 for drawing electricity from photovoltaic module 1700, in accordance with an embodiment of the present invention. In various embodiments of the present invention, positive terminal 1704 and negative terminal 1706 may be present at another location on base substrate 1702.

It is to be understood that the specific designation for the photovoltaic module and its components as shown in FIGS. 9-17 is for the convenience of the reader and is not to be construed as limiting the photovoltaic module and its components to a specific number, size, shape, type, material, or arrangement.

FIG. 18 illustrates a system 1800 for manufacturing a photovoltaic module, in accordance with an embodiment of the present invention. System 1800 includes a snap-fit attaching unit 1802, a stringer 1804, a strip arranger 1806, an optical-vee placer 1808, a positioning unit 1810, and a sealing unit 1811. System 1800 also includes a moulder 1812, a depositor 1814, a tool 1816, a polisher 1821a, a polisher 1821b, a bending unit 1820a, a sandwiching unit 1822, a bending unit 1820b, and a layer-forming unit 1824.

Snap-fit attaching unit 1202 attaches a plurality of connectors to base substrate 102. A plurality of connecting spaces is formed between the adjacent connectors. Snap-fit attaching unit 1802, for example, is a pick-and-place unit that picks a connector and attaches to the base substrate 102. Details of attaching the connectors to the base substrate 102 have been explained in detail in conjunction with FIGS. 2-8. Stringer 1804 connects the photovoltaic strips through one or more conductors in a predefined manner, such that one or more strings of photovoltaic strips are formed. Stringer 1804 may, for example, perform soldering using a manual process, a semi-automatic process, or a high-speed robotic assembly. Solder-coated copper strips may, for example, be used as the conductors. Alternatively, stringer 1804 may perform wire bonding using a high-speed robotic assembly.

Strip arranger 1806 arranges the strings of photovoltaic strips in the connecting spaces over the base substrate 102. Strip arranger 1806 may, for example, be a pick-and-place unit that picks the strings of photovoltaic strips, and aligns and places them as per a specified arrangement.

In accordance with another embodiment of the present invention, strip arranger 1806 arranges individual photovoltaic strips in the connecting spaces over the base substrate 102, and stringer 1804 connects the photovoltaic strips with each other through the conductors over the base substrate. In such a case, strip arranger 1806 may, for example, be a pick-and-place unit that picks photovoltaic strips, and aligns and places them as per a specified arrangement.

Optical-vee placer 1808 places the optical vees 106 to the base substrate 102 through the connectors. Optical-vee placer 1808 may, for example, be a pick-and-place unit that picks optical vees, and places and connects them as per the specified arrangement. Placement of optical vees 106 on the connectors, as described in FIGS. 2-8, connects the optical vees 106 to the base substrate 102. The optical vees may be fabricated in different ways. In accordance with an embodiment of the present invention, moulder 1812 moulds a polymeric material to form the optical vees, and depositor 1814 deposits a reflective material over the optical vees to form a reflective layer or surface. Moulder 1812 may, for example, perform injection molding to mould optical vees of a desired shape. Optical vees may, for example, be inverted-V-shaped, and may be either hollow or solid. Depositor 1814 may, for example, perform a suitable Physical Vapour Deposition (PVD) process, such as a sputter deposition process.

In accordance with another embodiment of the present invention, tool 1816 machines solid blocks of a reflective material to form the optical vees, and polisher 1821a polishes surfaces of the machined solid blocks to form a reflective layer or surface. Tool 1816 may, for example, be a lathe machine.

In accordance with yet another embodiment of the present invention, polisher 1821b polishes a sheet of a reflective material to form a reflective layer or surface, and bending unit 1820a bends the sheet to form at least one of said optical vees. Bending unit 1820a may, for example, perform an automatic process of bending the sheet in a desired shape of optical vees. Polisher 1821a and polisher 1821b may either be parts of a polishing unit, or be the same unit.

In accordance with still another embodiment of the present invention, sandwiching unit 1822 sandwiches a foil of a reflective material between two sheets to form a sandwiched foil, and bending unit 1820b bends the sandwiched foil to form at least one of said optical vees. The sheets may, for example, be made of any material that is an electrical insulator and is suitable for bending. Examples of such material include, but are not limited to, a polymeric material, a silicone, EVA, TPU, PVB, and a plastic. The sheets may be optically transparent, as desired. Bending unit 1820b may, for example, perform an automatic process of bending the sandwiched foil in a desired shape of optical vees. Bending unit 1820a and bending unit 1820b may be the same unit.

As the outer layers of the sandwiched foil are electrically insulated, optical vees made of such sandwiched foil may be placed in contact with the photovoltaic strips. No short-circuiting occurs in such an arrangement.

Layer-forming unit 1824 forms a reflection-enhancing layer over the optical vees to enhance the reflectivity of the optical vees, in accordance with an embodiment of the present invention.

With reference to FIG. 18, positioning unit 1810 positions a transparent member over the optical vees. Positioning unit 1810 may, for example, be a pick-and-place unit that picks the transparent member, and aligns and places it as per the specified arrangement. Thereafter, sealing unit 1811 seals the transparent member with the base substrate. In accordance with an embodiment of the present invention, the sealing is performed at the periphery. This may be accomplished by a resistive heating process using sealing rollers that melts a solder preform and forms a hermetic seal. Alternatively, the seal may be formed by a needle-dispensed epoxy, gasket sealing, glass frit, or EVA. In such a case, the seal so formed is non-hermetic, and an additional step of framing the photovoltaic module may be performed. This can be accomplished by mechanically attaching a frame to the photovoltaic module. The frame may be made of a metal or a metallic alloy. Aluminum may be used for this purpose, as it is cheaper and lighter than other metals and metallic alloys.

In accordance with an embodiment of the present invention, the base substrate, the connectors, the photovoltaic strips, the optical vees and the transparent member form the photovoltaic module in an integrated manner.

Various embodiments of the present invention provide an apparatus for generating electricity from solar energy. The apparatus includes supporting means, conducting means, concentrating means, converting means, connecting means and transparent means. Supporting means provides support to the photovoltaic module. Connecting means connects the concentrating means to the supporting means. These concentrating means include a reflective means, such that rays incident on the reflective means are reflected towards the converting means. The reflective means includes a reflective layer or surface. The reflective layer or surface may be made of reflective material. The concentrating means may be either hollow or solid. The connecting means include one or more connecting spaces between them. The converting means are placed in the connecting spaces between the connecting means. The converting means converts the solar energy into electrical energy. The conducting means connects the converting means in a predefined manner.

The transparent means is positioned over the concentrating means. The supporting means, the connecting means, the converting means, the concentrating means and the transparent means form the apparatus in an integrated manner. The transparent means is sealed with the supporting means. The transparent means is coated with an anti-reflective coating to reduce loss of solar energy incident on the apparatus, in accordance with an embodiment of the present invention.

Examples of the supporting means include base substrate 102. Examples of the connecting means include, but are not limited to, angular elements, Z-shaped elements, studs and flexible elements. Examples of the converting means include, but are not limited to, photovoltaic strips 104, and string configuration 1400. Examples of the means for connecting include, but are not limited to, conductors 1002a-d. Examples of the concentrating means include optical vees 106. Examples of the transparent means include transparent member 108.

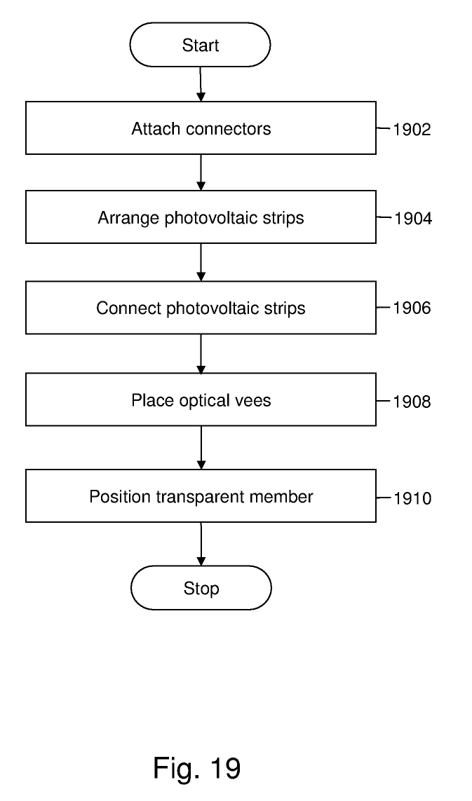

FIG. 19 is a flow diagram illustrating a method for fabricating a photovoltaic module, in accordance with an embodiment of the present invention. At step 1902, a plurality of connectors is attached to a base substrate. A plurality of connecting spaces is formed between the connectors.

At step 1904, one or more photovoltaic strips are arranged in the alternate connecting spaces over a base substrate. The shape of the photovoltaic strips, for example, may be rectangular, and may be arranged parallel to each other. Alternatively, the photovoltaic strips may be circular or arc-like in shape, and may be arranged in the form of concentric circles. The photovoltaic strips may also be square, triangular, or any other shape, in accordance with a desired configuration. The photovoltaic strips are capable of converting solar energy into electrical energy. At step 1906, the photovoltaic strips are connected through one or more conductors in a predefined manner. The predefined manner may, for example, be a series and/or parallel arrangement, such that electrical output is maximized. Details of various configurations of photovoltaic strips have been provided in conjunction with FIGS. 14 and 29.

At step 1908, a plurality of optical vees is placed and connected to the base substrate through the connectors. The optical vees are inverted-V-shaped in cross-section, in accordance with an embodiment of the present invention. In accordance with another embodiment of the present invention, the optical vees are compound-parabolic-shaped in cross-section. The optical vees may be either hollow or solid. These optical vees may, for example, be made of a glass, a plastic, a polymeric material, ethyl vinyl acetate (EVA), thermoplastic poly-urethane (TPU), poly vinyl butyral (PVB), a silicone, an acrylic, a polycarbonate, a metal, a metallic alloy, a metal compound, and a ceramic. The optical vees are capable of concentrating solar energy over the photovoltaic strips. The optical vees have a reflective layer or surface, such that rays incident on the reflective layer or surface are reflected towards the photovoltaic strips.

At step 1910, a transparent member is positioned over the optical vees. The transparent member protects the photovoltaic strips and the optical vees from environmental damage. Examples of the transparent member include, but are not limited to, glass, plastics, polymeric materials and EVA. The transparent member may, for example, be a toughened glass with low iron content, or be made of a polymeric material which is non-UV-degradable.

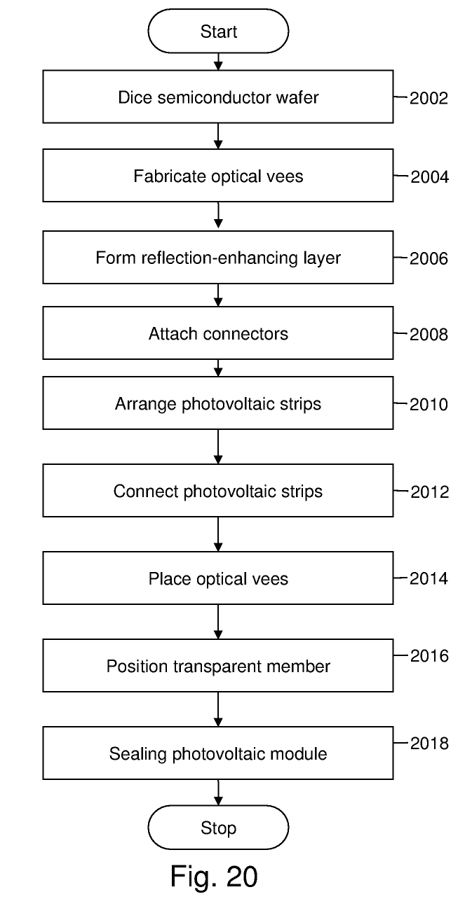

FIG. 20 is a flow diagram illustrating a method for manufacturing a photovoltaic module, in accordance with another embodiment of the present invention. At step 2002, a semiconductor wafer is diced to form one or more photovoltaic strips. This can be accomplished by mechanical sawing or laser dicing. In laser dicing, a semiconductor wafer is diced from its p-side using a laser source. This provides a clean cut without any burrs, and involves minimal material damage. At step 2004, optical vees are fabricated. Optical vees may be fabricated in various ways, as described earlier. At step 2006, a reflection-enhancing layer is formed over the optical vees to enhance the reflectivity of the optical vees.

At step 2008, a plurality of connectors is attached to a base substrate. A plurality of connecting spaces is formed between the connectors. At step 2010, one or more photovoltaic strips are arranged in the connecting spaces over the base substrate. At step 2012, the photovoltaic strips are connected through one or more conductors. This may be accomplished by manual soldering or by soldering using a high-speed soldering machine. Solder-coated copper strips may, for example, be used as the conductors. As mentioned above, the photovoltaic strips may be connected in a predefined manner. The predefined manner may, for example, be a series and/or parallel arrangement, such that electrical output is maximized. Details of various configurations of photovoltaic strips have been provided in conjunction with FIGS. 14 and 29.

At step 2014, a plurality of optical vees is placed and connected to the base substrate through the connectors. The plurality of optical vees are placed at both sides of the photovoltaic strips, such that solar energy is concentrated over the optical vees. As mentioned above, the optical vees have a reflective layer or surface, and may be either hollow or solid. The optical vees may, for example, be made of a glass, a plastic, a polymeric material, EVA, TPU, PVB, a silicone, an acrylic, a polycarbonate, a metal, a metallic alloy, a metal compound and a ceramic.

At step 2016, a transparent member is coated with an anti-reflective coating to reduce loss of solar energy incident on the photovoltaic module. Therefore, no reflection occurs at medium boundaries between air and the transparent member. The anti-reflective coating may, for example, be made of silicon nitride, an oxide of silicon, or an oxide of titanium.

At step 2018, the photovoltaic strips and the optical vees are sealed with the transparent member. The transparent member is positioned over the optical vees. The transparent member protects the photovoltaic strips and the optical vees from environmental damage, while allowing electromagnetic radiation falling on its surface to pass through it. The transparent member may, for example, be made of glass, plastics, polymeric materials and EVA. The transparent member may, for example, be a toughened glass with low iron content, or be made of a suitable polymeric material which is non-UV-degradable.

In an embodiment of the present invention, the transparent member is sealed around the corners to the base substrate, using a suitable material. This may be accomplished by a resistive heating process using sealing rollers that melts a solder preforms and forms a hermetic seal. The seal may also be formed by a needle-dispensed epoxy, gasket sealing, glass frit, or EVA. As the seal at the edge of the photovoltaic module so formed may remain non-hermetic, an additional step of framing the photovoltaic module may be performed. This can be accomplished by mechanically attaching a frame to the photovoltaic module. The frame may be made of a metal or a metallic alloy. Aluminium may be used for this purpose, as it is cheaper and lighter than other metals and metallic alloys.

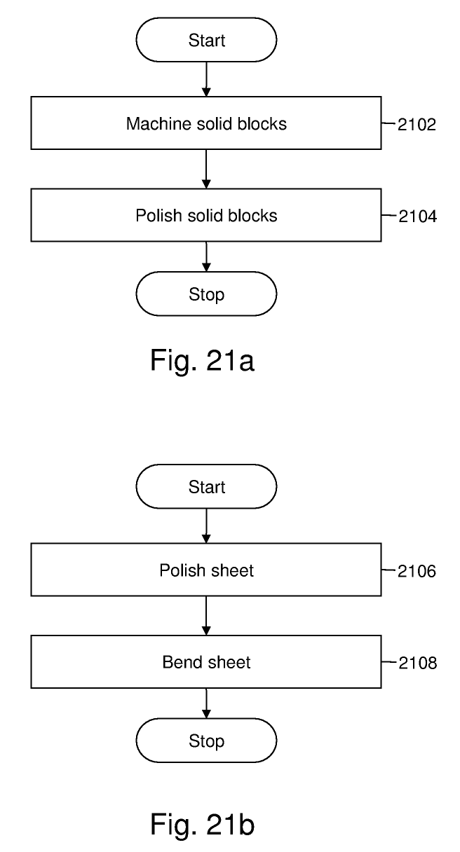

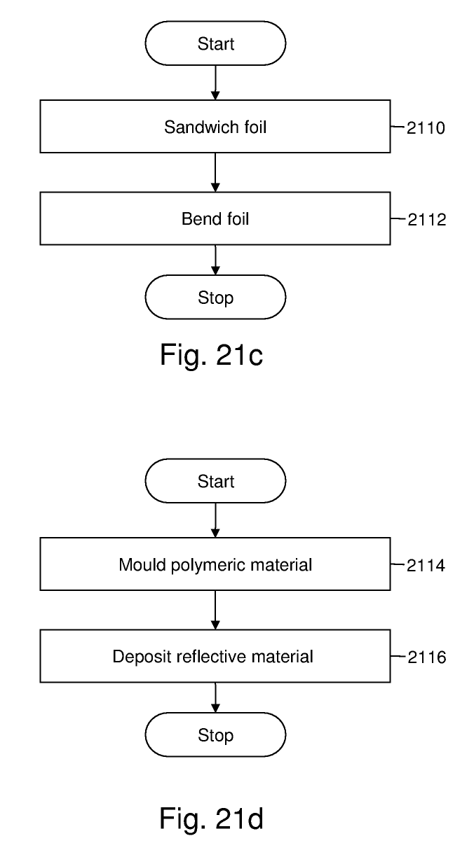

FIG. 21A-D illustrate various methods of fabricating optical vees. FIG. 21A illustrates a method of fabricating optical vees, in accordance with an embodiment of the present invention. At step 2102, solid blocks of a reflective material are machined to form the optical vees. At step 2104, surfaces of each solid block are polished to form a reflective layer or surface.

FIG. 21B illustrates a method of fabricating optical vees, in accordance with another embodiment of the present invention. At step 2106, a sheet of a reflective material is polished to form a reflective layer or surface. At step 2108, the polished sheet is bent to form at least one of the optical vees.

FIG. 21C illustrates a method of fabricating optical vees, in accordance with yet another embodiment of the present invention. At step 2110, a foil of a reflective material is sandwiched between two sheets to form a sandwiched foil. The sandwiched foil forms the reflective layer or surface. At step 2112, the sandwiched foil is bent to form at least one of the optical vees.

FIG. 21D illustrates a method of fabricating optical vees, in accordance with still another embodiment of the present invention. At step 2114, a polymeric material is molded to form the optical vees. At step 2116, a reflective material is deposited over the optical vees to form a reflective layer or surface.

The reflective material can be any metal, metallic alloy, or metal compound that is resistant to damage due to moisture and natural temperature variations, and has high reflectivity. Examples of such reflective material include, but are not limited to, aluminium, silver, nickel and steel. Aluminium may be used as a reflective material, as it is cheaper than other materials. However, in certain cases, silver may be used, as its reflectivity is sufficiently higher than aluminium to offset the difference in cost.

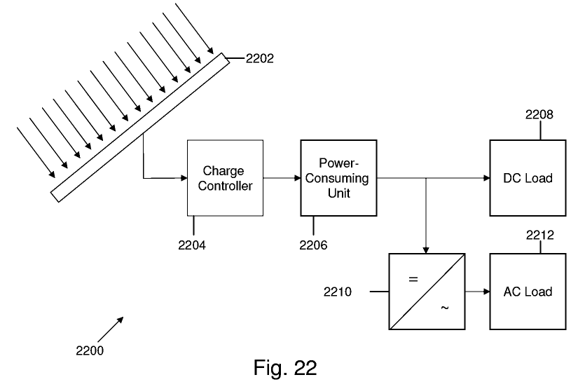

FIG. 22 illustrates a system 2200 for generating electricity from solar energy, in accordance with an embodiment of the present invention. System 2200 includes a photovoltaic module 2202, a charge controller 2204, a power-consuming unit 2206, a Direct Current (DC) load 2208, an inverter 2210 and an Alternating Current (AC) load 2212.

Photovoltaic module 2202 generates electricity from the solar energy that falls on photovoltaic module 2202. Photovoltaic module 2202 is similar to photovoltaic module 100. Power-consuming unit 2206 is connected with photovoltaic module 2202. Power-consuming unit 2206 consumes the charge generated by photovoltaic module 2202. Power-consuming unit 2206 may, for example, be a battery.

In an embodiment of the present invention, charge controller 2204 is connected with photovoltaic module 2202 and power-consuming unit 2206. Charge controller 2204 controls the amount of charge consumed in power-consuming unit 2206. For example, if the amount of charge stored in power-consuming unit 2206 exceeds a first threshold, charge controller 2204 discontinues further charging of power-consuming unit 2206. Similarly, if the amount of charge stored in power-consuming unit 2206 falls below a second threshold, charge controller 2204 reinitiates charging of power-consuming unit 2206. In an embodiment of the present invention, the first threshold and the second threshold lie between the maximum and the minimum capacity of power-consuming unit 2206.

Power-consuming unit 2206 produces electricity in a first form. In an embodiment of the present invention, the first form is a DC that can be utilized by DC load 2208. DC load 2208 may, for example, be a device that operates on DC. In another embodiment of the present invention, the first form is an AC that can be utilized by AC load 2212. AC load 2212 may, for example, be a device that operates on AC.

Inverter 2210 is connected with power-consuming unit 2206. Inverter 2210 converts electricity from the first form to a second form, as required. The second form may be either DC or AC. Consider, for example, that the first form is DC, and a device requires electricity in the second form, that is, AC. Inverter 2210 converts DC into AC.

System 2200 may be implemented at a roof top of a building, for home or office use. Alternatively, system 2200 may be implemented for use with stand-alone electrical devices, such as automobiles and spacecraft.

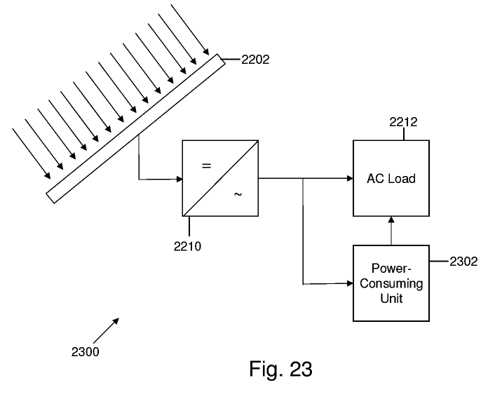

FIG. 23 illustrates a system 2300 for generating electricity from solar energy, in accordance with another embodiment of the present invention. System 2300 includes photovoltaic module 2102, inverter 2110, AC load 2112 and a power-consuming unit 2302.

As mentioned above, inverter 2110 converts electricity generated by photovoltaic module 2102 from the first form to the second form. With reference to FIG. 23, electricity in the second form is utilized by power-consuming unit 2302. Power-consuming unit 2102 may, for example, be a utility grid. For example, an array of photovoltaic modules 2302 may be used to generate electricity on a large scale for grid power supply.

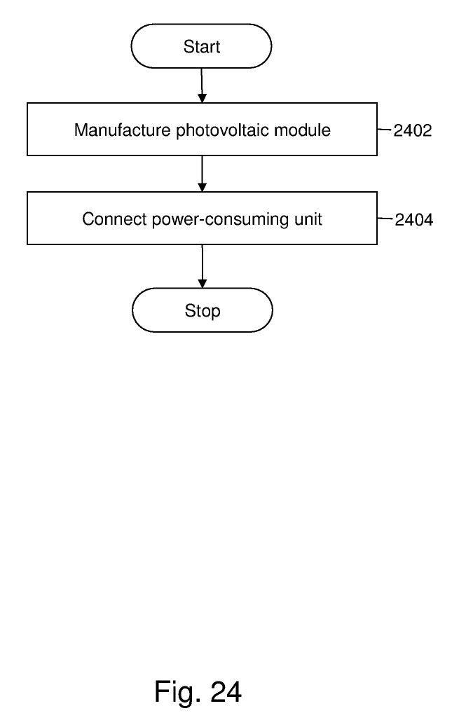

FIG. 24 illustrates a method for manufacturing a system for generating electricity from solar energy, in accordance with an embodiment of the present invention.

At step 2402, a photovoltaic module is manufactured as described earlier. The photovoltaic module may, for example, be photovoltaic module 100. At step 2404, a power-consuming unit is connected to the photovoltaic module. The power-consuming unit consumes the charge generated by the photovoltaic module. The power-consuming unit may either be a battery or a utility grid.

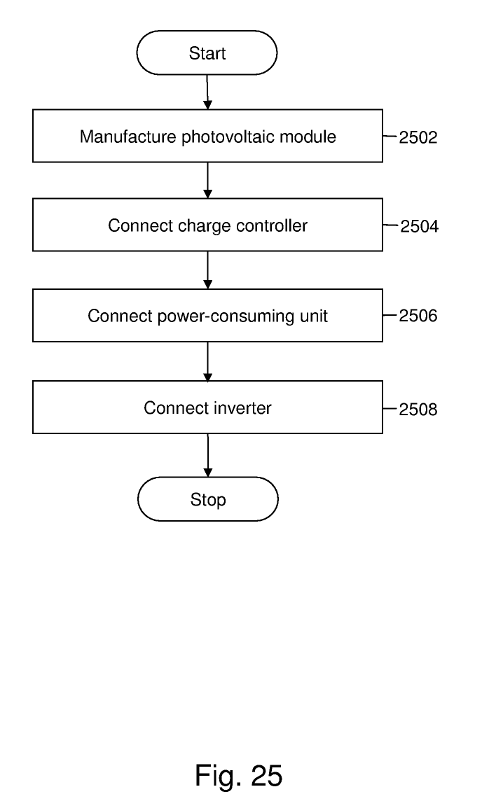

FIG. 25 illustrates a method for manufacturing a system for generating electricity from solar energy, in accordance with another embodiment of the present invention.

At step 2502, a photovoltaic module is manufactured as described earlier. The photovoltaic module may, for example, be photovoltaic module 100. At step 2504, a charge controller is connected with the photovoltaic module. At step 2506, a power-consuming unit is connected with the charge controller. As explained above, the charge controller controls the amount of charge stored in the power-consuming unit. For example, if the amount of charge stored in the power-consuming unit exceeds a first threshold, the charge controller discontinues further charging of the power-consuming unit. Similarly, if the amount of charge stored in the power-consuming unit falls below a second threshold, the charge controller reinitiates charging of the power-consuming unit. In an embodiment of the present invention, the first threshold and the second threshold lie between the maximum and the minimum capacity of the power-consuming unit.

The power-consuming unit provides the electricity in a first form. Devices that use the first form of electricity may directly be connected to the power-consuming unit. However, devices that use a second form of electricity, require that the first form be converted to the second form. At step 2508, an inverter is connected with the power-consuming unit. The inverter converts the electricity from the first form to the second form. Examples of the first form and the second form include DC and AC.

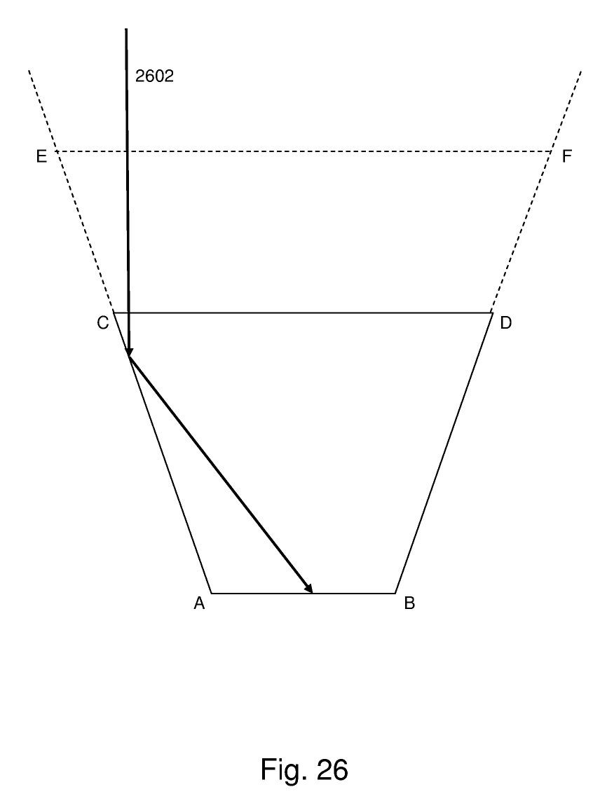

FIG. 26 illustrates how the level of concentration can be varied, in accordance with an embodiment of the present invention. AB represents an exit area through which rays exit, while CD represents a first entry area from where the rays enter. A first level of concentration is equal to the ratio of CD and AB. With reference to FIG. 26, the level of concentration is increased by increasing the height and the width of the empty area proportionally. EF represents a second entry area. A second level of concentration is equal to the ratio of EF and AB. The second level of concentration is greater than the first level of concentration, as EF is greater than CD.

In case of the first level of concentration, when a ray 2602 falls on side AC, it undergoes reflection towards AB as shown. In case of the second level of concentration, ray 2602 is reflected towards AB in the same manner.

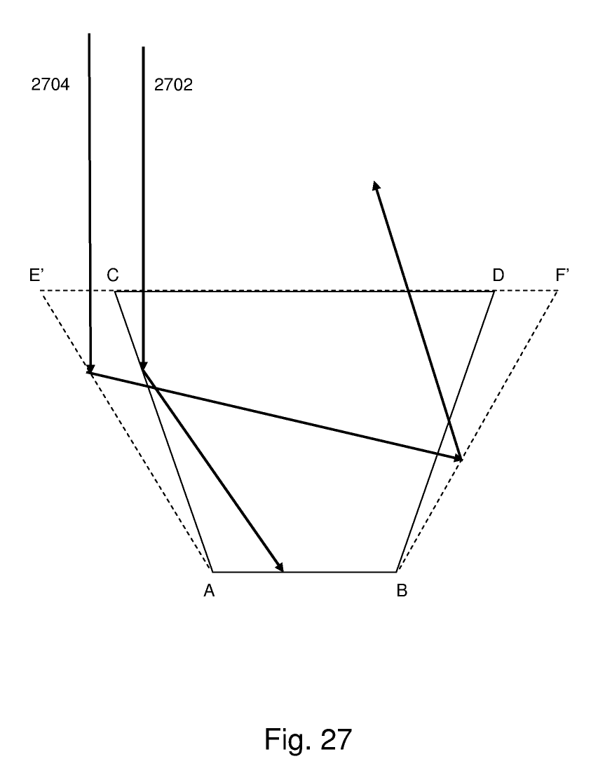

FIG. 27 illustrates how the level of concentration can be varied, in accordance with an embodiment of the present invention. AB represents the exit area, while CD represents the first entry area. The first level of concentration is equal to the ratio of CD and AB. With reference to FIG. 27, the level of concentration is increased by increasing the width of the empty area without varying the height of the empty area. E′F′ represents a third entry area. A third level of concentration is numerically equal to the ratio of E′F′ and AB, and the third level of concentration is numerically greater than the first level of concentration, as E′F′ is greater than CD.

In case of the first level of concentration, when a ray 2702 falls on side AC, it undergoes reflection towards AB as shown. In case of the third level of concentration, when a ray 2704 falls on side AE′, it undergoes reflection towards BF′ as shown. Ray 2704 undergoes another reflection at BF′, and exits from E′F′. This leads to wastage of solar energy. Therefore, it can be concluded that the actual value of the third level of concentration is less than its numerical value.

It can be concluded that the acceptance angle of photovoltaic module 100 should be chosen appropriately. The acceptance angle is defined as the angle from the normal at which the power output from photovoltaic module 100 drops to a predefined value. The degree of acceptance angle varies with the geometry of the concentrator, which in turn is dependent on the level of optical concentration. For example, the acceptance angle may vary when the concentration is varied between 5:1 and 1.5:1.

Tracking mechanisms may be used to change the position of photovoltaic module 100, in order to keep the rays normally incident upon photovoltaic module 100 while the sun moves across the sky. This further enhances the power output of photovoltaic module 100.

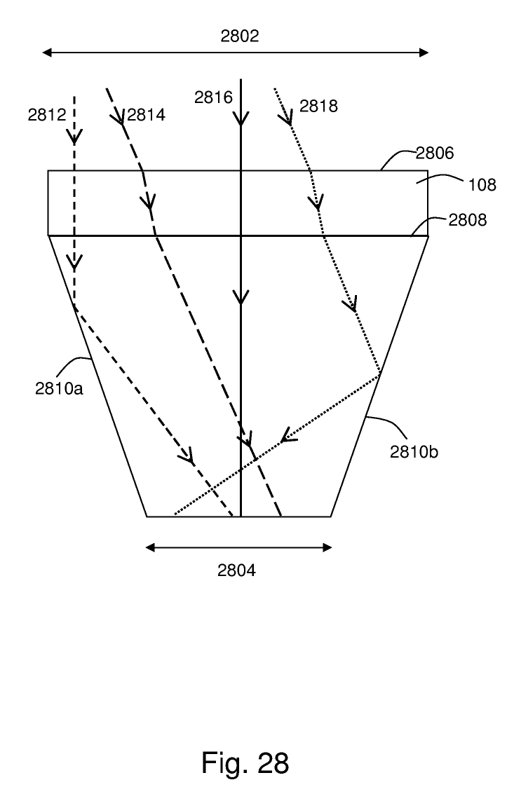

FIG. 28 is a cross-sectional view illustrating how electromagnetic radiation is concentrated over photovoltaic strips 104, in accordance with an embodiment of the present invention. A single low concentrator unit is shown. A portion of transparent member 108 over the empty space between two adjacent optical vees is shown. A photovoltaic strip (not shown in the figure) is placed between the two adjacent optical vees. The portion of transparent member 108 has an entry area 2802 through which rays enter, while the empty space has an exit area 2804, through which the rays exit towards the photovoltaic strip.

A medium boundary 2806 is formed between transparent member 108 and air. The refractive index of transparent member 108 is greater than the refractive index of air. Therefore, a ray passing from air to transparent member 108 is refracted towards the normal to medium boundary 2806, i.e., the angle of refraction is smaller than the angle of incidence.

A medium boundary 2808 is formed between transparent member 108 and air or vacuum in the empty space. The refractive index of transparent member 108 is greater than the refractive index of air or vacuum. Therefore, a ray passing from transparent member 108 to air is refracted away from the normal, i.e., the angle of refraction is greater than the angle of incidence.

With reference to FIG. 28, a ray 2812 is incident on medium boundary 2806 at an angle of incidence equal to zero. Ray 2812 passes through transparent member 108 and the empty area without any refraction. When incident on a side 2810a of an optical vee, ray 2812 undergoes reflection, and falls on the photovoltaic strip.

With reference to FIG. 28, a ray 2814 is incident on medium boundary 2806 at a non-zero angle of incidence. Ray 2814 refracts with a first angle of refraction smaller than its angle of incidence. When incident on medium boundary 2808, ray 2814 refracts again, with a second angle of refraction greater than its angle of incidence at medium boundary 2808, and falls on the photovoltaic strip.

With reference to FIG. 28, a ray 2816 is incident on medium boundary 2806 at an angle of incidence equal to zero. Ray 2816 passes through transparent member 108 and the empty area without any refraction, and falls on the photovoltaic strip.

With reference to FIG. 28, a ray 2818 is incident on medium boundary 2806 at a non-zero angle of incidence. Ray 2218 refracts with an angle of refraction smaller than its angle of incidence. When incident on medium boundary 2208, ray 2218 refracts again, with a second angle of refraction greater than its angle of incidence at medium boundary 2208. Further, when incident on a side 2210b of another optical vee, ray 2218 undergoes reflection, and falls on the photovoltaic strip.

FIG. 29 is a schematic diagram illustrating a configuration of one or more photovoltaic strips, in accordance with another embodiment of the present invention. With reference to FIG. 29, the photovoltaic strips are connected in series and parallel, such that the electrical output is maximized. In this configuration, three photovoltaic strips, such as a photovoltaic strip 2902a, a photovoltaic strip 2902b and a photovoltaic strip 2902c, are connected in series to form a first string. Similarly, a photovoltaic strip 2902d, a photovoltaic strip 2902e and a photovoltaic strip 2902f are connected in series to form a second string; a photovoltaic strip 2902g, a photovoltaic strip 2902h and a photovoltaic strip 2902i are connected in series to form a third string; a photovoltaic strip 2902j, a photovoltaic strip 2902k and a photovoltaic strip 29021 are connected in series to form a fourth string. These four strings are then combined in parallel.

It is to be understood that the specific designation for the configuration of photovoltaic strips in FIG. 29 is for the convenience of the reader and is not to be construed as limiting a photovoltaic module to a specific number or arrangement of its components.

The potential difference is directly proportional to the number of photovoltaic strips connected in series, while the current is directly proportional to the number of photovoltaic strips connected in parallel. The photovoltaic strips may be connected in series and parallel to create a configuration with a desired potential difference and current.

Table 1 is an exemplary table illustrating simulated data comparison between various types of photovoltaic modules, in accordance with an embodiment of the present invention.

TABLE 1

| Configuration | Unit | Concentration | Size (in mm) | Iₘ (in A) | Vₘ (in V) | Pₘ (in W) |
|---|---|---|---|---|---|---|
| 1 × 1 | Strip | 1:1 | 156 × 156 | 7.110 | 0.477 | 3.39 |
| 1 × 1 | Strip | 1:1 | 156 × 12 | 0.547 | 0.477 | 0.26 |
| 12 × 1 | Strip | 1:1 | 156 × 12 | 0.547 | 5.724 | 3.13 |
| 3(series) × | String | 1:1 | 156 × 12 × 12 | 2.188 | 17.172 | 37.57 |
| 4(parallel) | | | | | | |
| 3(series) × | String | 2:1 | 156 × 12 × 12 | 3.982 | 17.172 | 68.38 |
| 4(parallel) | | | | | | |
| 3(series) × | String | 3:1 | 156 × 12 × 12 | 5.973 | 17.172 | 102.568 |
| 4(parallel) | | | | | | |
| 3(series) × | String | 4:1 | 156 × 12 × 12 | 7.964 | 17.172 | 136.758 |
| 4(parallel) | | | | | | |
| 3(series) × | String | 5:1 | 156 × 12 × 12 | 9.955 | 17.172 | 170.954 |
| 4(parallel) | | | | | | |

With reference to Table 1,
‘Configuration’ denotes the configuration in which one or more photovoltaic strips are arranged to form a photovoltaic module;
‘Unit’ denotes the unit of the configuration;
‘Concentration’ denotes the level of concentration used in the photovoltaic module;
‘Size’ denotes the size of the photovoltaic strips used, in mm;
‘Im’ denotes the maximum current attained in the photovoltaic module, in ampere (A);
‘Vm’ denotes the maximum potential difference attained in the photovoltaic module, in volt (V); and
‘Pₘ’ denotes the maximum power developed in the photovoltaic module, in watt (W).

A first photovoltaic module has the configuration of ‘1×1’, the concentration of ‘1:1’ and the size of ‘156 mm×156 mm’. This implies that a single semiconductor wafer of size 156 mm×156 mm has been used without an additional concentrator.

The single semiconductor wafer is diced into 13 photovoltaic strips of size ‘156 mm×12 mm’ each. A second photovoltaic module is formed by a single photovoltaic strip of size 156 mm×12 mm without an additional concentrator.

A third photovoltaic module is formed by connecting 12 photovoltaic strips of size ‘156 mm×12 mm’ in series, without an additional concentrator. The 12 photovoltaic strips form one photovoltaic string.

A fourth photovoltaic module is formed by connecting three photovoltaic strings of size ‘156 mm×12 mm×12 nos.’ in series and combining four such configurations in parallel, without an additional concentrator. With reference to Table 1, the maximum current attained in the fourth photovoltaic module is four times the maximum current attained in the third photovoltaic module, while the maximum potential difference attained in the fourth photovoltaic module is thrice the maximum potential difference attained in the third photovoltaic module. Consequently, the maximum power developed in the fourth photovoltaic module is 12 times the maximum power developed in the third photovoltaic module.

A fifth photovoltaic module is formed by connecting three photovoltaic strings of size ‘156 mm×12 mm×12 nos.’ in series and combining four such configurations in parallel, with a concentrator providing a level of concentration of two. With reference to Table 1, the maximum current attained in the fifth photovoltaic module is nearly twice the maximum current attained in the fourth photovoltaic module. Consequently, the maximum power developed in the fifth photovoltaic module is nearly twice the maximum power developed in the fourth photovoltaic module.

A sixth photovoltaic module is formed by connecting three photovoltaic strings of size ‘156 mm×12 mm×12 nos.’ in series and combining four such configurations in parallel, with a concentrator providing a level of concentration of three. With reference to Table 1, the maximum current attained in the sixth photovoltaic module is nearly thrice the maximum current attained in the fourth photovoltaic module. Consequently, the maximum power developed in the sixth photovoltaic module is nearly thrice the maximum power developed in the fourth photovoltaic module.

A seventh photovoltaic module is formed by connecting three photovoltaic strings of size ‘156 mm×12 mm×12 nos.’ in series and combining four such configurations in parallel, with a concentrator providing a level of concentration of four. With reference to Table 1, the maximum current attained in the seventh photovoltaic module is nearly four times the maximum current attained in the fourth photovoltaic module. Consequently, the maximum power developed in the seventh photovoltaic module is nearly four times the maximum power developed in the fourth photovoltaic module.

A eighth photovoltaic module is formed by connecting three photovoltaic strings of size ‘156 mm×12 mm×12 nos.’ in series and combining four such configurations in parallel, with a concentrator providing a level of concentration of five. With reference to Table 1, the maximum current attained in the eighth photovoltaic module is nearly five times the maximum current attained in the fourth photovoltaic module. Consequently, the maximum power developed in the eighth photovoltaic module is nearly five times the maximum power developed in the fourth photovoltaic module. It should be appreciated that the maximum current attained and the maximum power developed in a photovoltaic module are directly proportional to the level of concentration provided in the photovoltaic module. As mentioned above, the level of concentration is measured by the ratio of the entry area and the exit area.

Embodiments of the present invention provide a photovoltaic module that is suitable for mass manufacturing, has lower cost, and is easy to manufacture compared to conventional low concentrator photovoltaic modules.

In accordance with an exemplary embodiment of the present invention, the method for fabricating the photovoltaic module involves the use of plastic and aluminium for manufacture of various components. This makes the photovoltaic module cheaper and light-weight compared to conventional photovoltaic modules.

Furthermore, the photovoltaic module provides maximized outputs, at appropriate configurations of the photovoltaic strips. Moreover, the photovoltaic module is made of photovoltaic strips, which are arranged with spaces in between two adjacent optical vees. Therefore, the photovoltaic module requires lesser amount of semiconductor material to produce the same output, as compared to conventional photovoltaic modules

This application may disclose several numerical range limitations that support any range within the disclosed numerical ranges even though a precise range limitation is not stated verbatim in the specification because the embodiments of the invention could be practiced throughout the disclosed numerical ranges. Finally, the entire disclosure of the patents and publications referred in this application, if any, are hereby incorporated herein in entirety by reference.

1. An apparatus for generating electricity from solar energy, said apparatus comprising:
a base substrate;
a plurality of connectors attached to said base substrate, wherein connecting spaces are formed between adjacent said connectors;
one or more photovoltaic strips arranged in said connecting spaces over said base substrate;
a plurality of optical vees for concentrating solar energy over said photovoltaic strips, said optical vees being connected to said base substrate through said connectors, said optical vees comprising a reflective layer or surface, such that rays incident on said reflective layer or surface are reflected towards said photovoltaic strips; and
a transparent member positioned over said optical vees,
wherein said base substrate, said connectors, said photovoltaic strips, said optical vees and said transparent member form said apparatus in an integrated manner.

2. The apparatus of claim 1, said photovoltaic strips being connected through one or more conductors in a predefined manner, wherein said predefined manner is a series and/or parallel arrangement.

3. The apparatus of claim 1, wherein said connectors are elongated Z-shaped elements.

4. The apparatus of claim 1, wherein said connectors are angular elements.

5. The apparatus of claim 1, wherein said connectors are flexible elements.

6. The apparatus of claim 1, wherein said optical vees comprise a polymeric material, and said reflective layer or surface comprises a reflective material.

7. The apparatus of claim 1, wherein said reflective layer or surface comprises a sandwiched foil comprising a foil of a reflective material between two sheets.

8. The apparatus of claim 1, wherein said optical vees comprise one or more extended portions extending outwards of said optical vees.

9. The apparatus of claim 1, wherein said optical vees are configured to slide through said connectors.

10. The apparatus of claim 1, wherein said optical vees further comprise a plurality of holes for connecting said optical vees to said base substrate through said connectors.

11. The apparatus of claim 1, wherein said optical vees are hollow.

12. The apparatus of claim 1, wherein said optical vees are solid.

13. The apparatus of claim 1, wherein said optical vees are made of a material selected from the group consisting of glass, a plastic, ethyl vinyl acetate (EVA), a thermoplastic poly-urethane (TPU), poly vinyl butyral (PVB), a silicone, an acrylic, a polycarbonate, a metal, a metallic alloy, a metal compound and a ceramic.

14. An apparatus comprising:
supporting means for providing support to said apparatus;
converting means for converting solar energy into electrical energy;
conducting means for electrically connecting said converting means in a predefined manner;
concentrating means for concentrating solar energy over said converting means, said concentrating means comprising reflective means, such that rays incident on said reflective means are reflected towards said converting means;
connecting means for connecting said concentrating means to said supporting means, said connecting means attached to said supporting means, wherein connecting spaces are formed between adjacent said connecting means, such that said converting means are arranged in said connecting spaces over said supporting means; and
transparent means positioned over said concentrating means,
wherein said supporting means, said converting means, said connecting means, said concentrating means and said transparent means form said apparatus in an integrated manner.

15. The apparatus of claim 14, wherein said concentrating means comprise solid blocks of a reflective material.

16. The apparatus of claim 14, wherein said reflective means comprises a sandwiched foil comprising a foil of a reflective material between two sheets.

17. The apparatus of claim 14, wherein said concentrating means comprises one or more extended portions extending outwards of said concentrating means.

18. A system for manufacturing a photovoltaic module, the system comprising:
a snap-fit attaching unit for attaching a plurality of connectors to a base substrate, wherein connecting spaces are formed between adjacent said connectors;
a strip-arranger for arranging one or more photovoltaic strips in said connecting spaces over said base substrate, said photovoltaic strips being capable of converting solar energy into electrical energy;
a stringer for connecting said photovoltaic strips through one or more conductors in a predefined manner;
an optical-vee placer for connecting a plurality of optical vees to said base substrate through said connectors, said optical vees being capable of concentrating solar energy over said photovoltaic strips, said optical vees comprising a reflective layer or surface, such that rays incident on said reflective layer or surface are reflected towards said photovoltaic strips; and
a positioning unit for positioning a transparent member over said optical vees,
wherein said base substrate, said connectors, said photovoltaic strips, said optical vees and said transparent member form said photovoltaic module in an integrated manner.

19. The system of claim 18, wherein said connectors are elongated Z-shaped elements.

20. The system of claim 18, wherein said connectors are angular elements.

21-40. (canceled)
